(19) United States
(12) Patent Application Publication
(10) Pub. No.: US 2026/0081622 A1
(43) Pub. Date: Mar. 19, 2026

(54) POLAR CODE CONSTRUCTION AND CONFIGURATION FOR BLOCK-CODE-BASED SHAPING

(71) Applicant: QUALCOMM Incorporated, San Diego, CA (US)

(72) Inventors: Liangming WU, Beijing (CN); Wei LIU, Beijing (CN); Jian LI, Shanghai (CN); Jing JIANG, San Diego, CA (US); Wei YANG, San Diego, CA (US); Kexin XIAO, Shanghai (CN); Changlong XU, Beijing (CN); Hao XU, Beijing (CN)

(21) Appl. No.: 18/871,421

(22) PCT Filed: Jul. 18, 2022
(86) PCT No.: PCT/CN2022/106200

§ 371 Date: Dec. 3, 2024

(51) Int. Cl. H03M 13/13; H03M 13/00; H03M 13/39; H04L 1/00

(52) U.S. Cl. CPC H03M 13/13; H03M 13/3927; H03M 13/611; H04L 1/0025; H04L 1/0045; H04L 1/0057

(57) ABSTRACT

Certain aspects of the present disclosure provide techniques for Polar code construction and configuration for block-code-based shaping. An example method includes identifying a set of information bits for transmission, generating a set of log likelihood ratios (LLRs) corresponding to the set of information bits, segmenting the set of LLRs into a plurality of shaping blocks based, at least in part, on a shaping block length for the plurality of shaping blocks, decoding, according to a shaping code rate, the plurality of shaping blocks using a polar code to obtain a sequence of shaping bits, wherein the polar code used to decode the plurality of shaping blocks depends on the shaping code rate and the shaping block length, generating a sequence of shaped symbols from the sequence of shaping bits, transmitting the sequence of shaped symbols to a receiving device.

### BACKGROUND

### Field of the Disclosure

Aspects of the present disclosure relate to wireless communications, and more particularly, to techniques for Polar code construction and configuration for block-code-based shaping.

### Description of Related Art

Wireless communications systems are widely deployed to provide various telecommunication services such as telephony, video, data, messaging, broadcasts, or other similar types of services. These wireless communications systems may employ multiple-access technologies capable of supporting communications with multiple users by sharing available wireless communications system resources with those users

Although wireless communications systems have made great technological advancements over many years, challenges still exist. For example, complex and dynamic environments can still attenuate or block signals between wireless transmitters and wireless receivers. Accordingly, there is a continuous desire to improve the technical performance of wireless communications systems, including, for example: improving speed and data carrying capacity of communications, improving efficiency of the use of shared communications mediums, reducing power used by transmitters and receivers while performing communications, improving reliability of wireless communications, avoiding redundant transmissions and/or receptions and related processing, improving the coverage area of wireless communications, increasing the number and types of devices that can access wireless communications systems, increasing the ability for different types of devices to intercommunicate, increasing the number and type of wireless communications mediums available for use, and the like. Consequently, there exists a need for further improvements in wireless communications systems to overcome the aforementioned technical challenges and others.

### SUMMARY

One aspect provides a method for wireless communications by a transmitting device. The method includes identifying a set of information bits for transmission; generating a set of log likelihood ratios (LLRs) corresponding to the set of information bits; segmenting the set of LLRs into a plurality of shaping blocks based, at least in part, on a shaping block length for the plurality of shaping blocks; decoding, according to a shaping code rate, the plurality of shaping blocks using a polar code to obtain a sequence of shaping bits, wherein the polar code used to decode the plurality of shaping blocks depends on the shaping code rate and the shaping block length; generating a sequence of shaped symbols from the sequence of shaping bits; and transmitting the sequence of shaped symbols to a receiving device.

One aspect provides a method for wireless communication by a receiving device. The method includes receiving, from a transmitting device, a sequence of shaped symbols corresponding to a sequence of bit-level log likelihood ratios (LLRs); converting the sequence of shaped symbols to the sequence of bit-level LLRs; decoding, using a forward error correction (FEC) code rate, the sequence of bit-level LLRs to obtain a sequence of shaped information bits of a set of information bits, a sequence of shaping bits, and a remaining subset of non-shaped information bits of the set of information bits; performing, using a shaping code rate, a deshaping operation on the sequence of shaped information bits based on the sequence of shaping bits to obtain a sequence of deshaped information bits; and concatenating the sequence of deshaped information bits with the remaining subset of non-shaped information bits to obtain the set of information bits.

Other aspects provide: an apparatus operable, configured, or otherwise adapted to perform any one or more of the aforementioned methods and/or those described elsewhere herein; a non-transitory, computer-readable media comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example wireless communications network.

FIG. 2 depicts an example disaggregated base station architecture.

FIG. 3 depicts aspects of an example base station and an example user equipment.

FIGS. 4A, 4B, 4C, and 4D depict various example aspects of data structures for a wireless communications network.

FIG. 5 depicts an example implementation of a transmitter and receiver.

FIG. 6 illustrates a communication system, including a transmitter and a receiver, employing probabilistic amplitude shaping based on a block code.

FIG. 7 depicts a method for wireless communications.

FIG. 8 depicts a method for wireless communications.

FIG. 9 depicts aspects of an example communications device.

FIG. 10 depicts aspects of an example communications device.

### DETAILED DESCRIPTION

Aspects of the present disclosure provide apparatuses, methods, processing systems, and computer-readable mediums for Polar code construction and configuration for block-code-based shaping.

For example, in some cases, wireless communication may use a technique known as probabilistic amplitude shaping (PAS). A goal of PAS is to minimize an average signal power of a transmitted signal and to increase the throughput of a wireless communication network. In some cases, to minimize the average signal power of a transmitted signal, a shaping operation may be performed to modify a bit sequence of the transmitted signal, which may involve applying a bit-mask to a most significant bit (MSB) of the bit sequence to lower the average signal power of the transmitted signal. For example, a bit-level and symbol transmit power may have a certain relationship in which a first bit (e.g., b0) may control the transmit power of a symbol ‘s’ of the transmitted signal than other bits. As a result, if bit b0 is transmitted with a bit value of 0 (zero), then the transmit power associated with symbol ‘s’ of the transmitted signal may be lower as compared to a bit value of 1 (one).

In some cases, the shaping operation may be based on a shaping codeword used to bit-mask a subset of a set of information bits corresponding to amplitude symbols. In some cases, the shaping codeword may be generated based on sequence of shaping bits (e.g., generated based on the set of information bits) and a block code, such as a Polar code. Polar codes can achieve a “rate-distortion” bound for lossy data compression and, as such, it may be beneficial to use Polar codes for bit-level shaping to provide good data compression. Polar codes are linear block codes defined by (N, K) where N=2 and is the block length and K a length of the sequence of shaping bits. In some cases, to avoid certain issues that may arise when using Polar codes, the block length N and information bit length K may need to be taken into account when constructing and using Polar codes for block-code-based probabilistic amplitude shaping. For example, in some cases, if too large of a value for Nis used when constructing a Polar code, Polar decoding at a receiver may be too complex and may take too long, resulting in an increase consumption of processing resources and power consumption, as well as poor user experience. Additionally, because K controls the number of shaping bits used to perform probabilistic amplitude shaping, selecting a proper number of K is thus important for the shaping performance.

Accordingly, aspects of the present disclosure provide techniques for Polar code construction and configuration for block-code-based shaping. More specifically, for example, aspects of the present disclosure provide techniques for constructing Polar codes that may be used to perform probabilistic amplitude shaping on a set of information bits for transmission. In some cases, these techniques may include taking into account the block length and length of shaping bits when constructing Polar codes for use in probabilistic amplitude shaping. By taking into account the block length and length of shaping bits when constructing Polar codes, a suitable value of N may be selected to reduce decoding complexity and latency, thereby reducing power and processing resource consumption at a receiver and improving user experience.

### Introduction to Wireless Communications Networks

The techniques and methods described herein may be used for various wireless communications networks. While aspects may be described herein using terminology commonly associated with 3G, 4G, and/or 5G wireless technologies, aspects of the present disclosure may likewise be applicable to other communications systems and standards not explicitly mentioned herein.

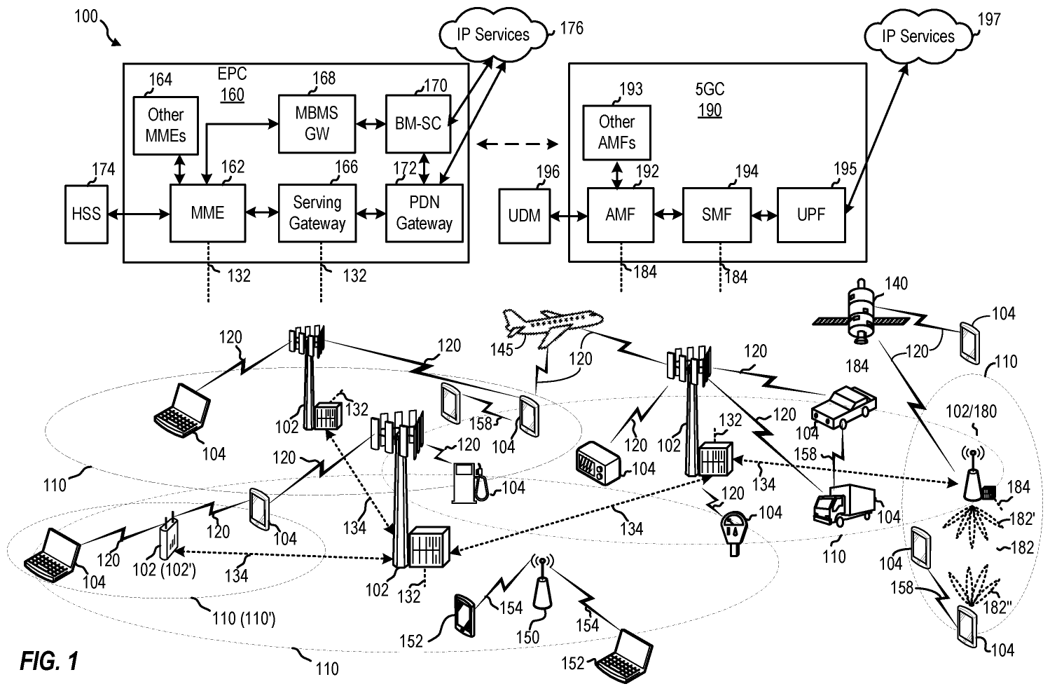

FIG. 1 depicts an example of a wireless communications network 100, in which aspects described herein may be implemented.

Generally, wireless communications network 100 includes various network entities (alternatively, network elements or network nodes). A network entity is generally a communications device and/or a communications function performed by a communications device (e.g., a user equipment (UE), a base station (BS), a component of a BS, a server, etc.). For example, various functions of a network as well as various devices associated with and interacting with a network may be considered network entities. Further, wireless communications network 100 includes terrestrial aspects, such as ground-based network entities (e.g., BSs 102), and non-terrestrial aspects, such as satellite 140 and aircraft 145, which may include network entities on-board (e.g., one or more BSs) capable of communicating with other network elements (e.g., terrestrial BSs) and user equipments.

In the depicted example, wireless communications network 100 includes BSs 102, UEs 104, and one or more core networks, such as an Evolved Packet Core (EPC) 160 and 5G Core (5GC) network 190, which interoperate to provide communications services over various communications links, including wired and wireless links.

FIG. 1 depicts various example UEs 104, which may more generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. UEs 104 may also be referred to more generally as a mobile device, a wireless device, a wireless communications device, a station, a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and others.

BSs 102 wirelessly communicate with (e.g., transmit signals to or receive signals from) UEs 104 via communications links 120. The communications links 120 between BSs 102 and UEs 104 may include uplink (UL) (also referred to as reverse link) transmissions from a UE 104 to a BS 102 and/or downlink (DL) (also referred to as forward link) transmissions from a BS 102 to a UE 104. The communications links 120 may use multiple-input and multiple-output (MIMO) antenna technology, including spatial multiplexing, beamforming, and/or transmit diversity in various aspects.

BSs 102 may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. Each of BSs 102 may provide communications coverage for a respective geographic coverage area 110, which may sometimes be referred to as a cell, and which may overlap in some cases (e.g., small cell 102′ may have a coverage area 110′ that overlaps the coverage area 110 of a macro cell). A BS may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

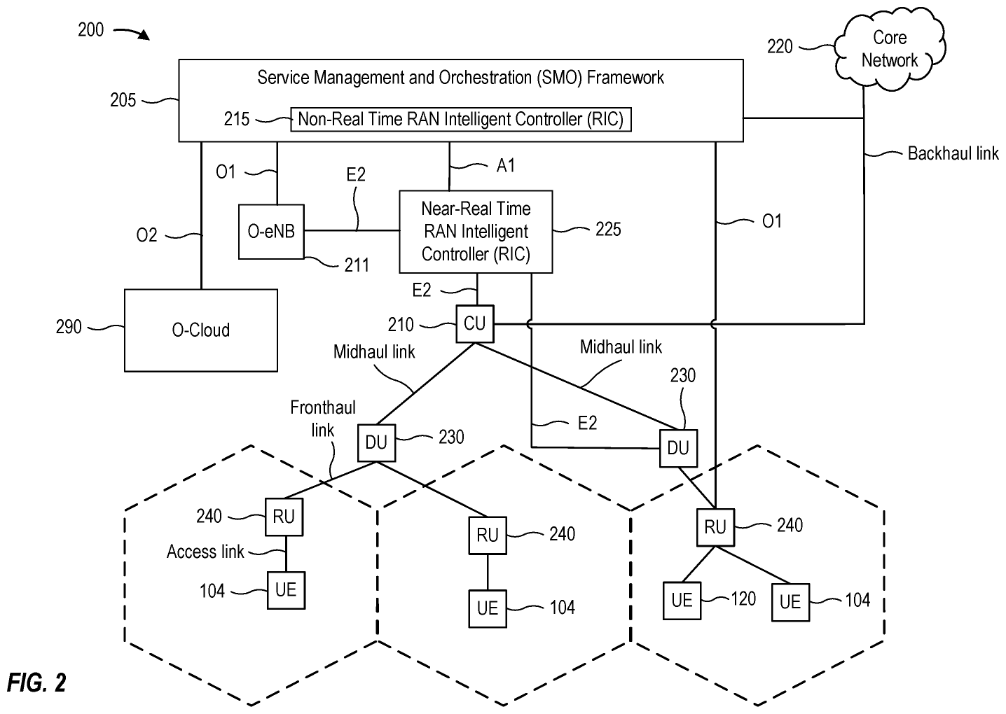

While BSs 102 are depicted in various aspects as unitary communications devices, BSs 102 may be implemented in various configurations. For example, one or more components of a base station may be disaggregated, including a central unit (CU), one or more distributed units (DUs), one or more radio units (RUs), a Near-Real Time (Near-RT) RAN Intelligent Controller (RIC), or a Non-Real Time (Non-RT) RIC, to name a few examples. In another example, various aspects of a base station may be virtualized. More generally, a base station (e.g., BS 102) may include components that are located at a single physical location or components located at various physical locations. In examples in which a base station includes components that are located at various physical locations, the various components may each perform functions such that, collectively, the various components achieve functionality that is similar to a base station that is located at a single physical location. In some aspects, a base station including components that are located at various physical locations may be referred to as a disaggregated radio access network architecture, such as an Open RAN (O-RAN) or Virtualized RAN (VRAN) architecture. FIG. 2 depicts and describes an example disaggregated base station architecture.

Different BSs 102 within wireless communications network 100 may also be configured to support different radio access technologies, such as 3G, 4G, and/or 5G. For example, BSs 102 configured for 4G LTE (collectively referred to as Evolved Universal Mobile Telecommunications System (UMTS) Terrestrial Radio Access Network (E-UTRAN)) may interface with the EPC 160 through first backhaul links 132 (e.g., an S1 interface). BSs 102 configured for 5G (e.g., 5G NR or Next Generation RAN (NG-RAN)) may interface with 5GC 190 through second backhaul links 184. BSs 102 may communicate directly or indirectly (e.g., through the EPC 160 or 5GC 190) with each other over third backhaul links 134 (e.g., X2 interface), which may be wired or wireless.

Wireless communications network 100 may subdivide the electromagnetic spectrum into various classes, bands, channels, or other features. In some aspects, the subdivision is provided based on wavelength and frequency, where frequency may also be referred to as a carrier, a subcarrier, a frequency channel, a tone, or a subband. For example, 3GPP currently defines Frequency Range 1 (FR1) as including 410 MHz-7125 MHz, which is often referred to (interchangeably) as “Sub-6 GHz”. Similarly, 3GPP currently defines Frequency Range 2 (FR2) as including 24,250 MHz-52,600 MHz, which is sometimes referred to (interchangeably) as a “millimeter wave” (“mmW” or “mmWave”). A base station configured to communicate using mmWave/near mmWave radio frequency bands (e.g., an mmWave base station such as BS 180) may utilize beamforming (e.g., 182) with a UE (e.g., 104) to improve path loss and range.

The communications links 120 between BSs 102 and, for example, UEs 104, may be through one or more carriers, which may have different bandwidths (e.g., 5, 10, 15, 20, 100, 400, and/or other MHz), and which may be aggregated in various aspects. Carriers may or may not be adjacent to each other. Allocation of carriers may be asymmetric with respect to DL and UL (e.g., more or fewer carriers may be allocated for DL than for UL).

Communications using higher frequency bands may have higher path loss and a shorter range compared to lower frequency communications. Accordingly, certain base stations (e.g., 180 in FIG. 1) may utilize beamforming 182 with a UE 104 to improve path loss and range. For example, BS 180 and the UE 104 may each include a plurality of antennas, such as antenna elements, antenna panels, and/or antenna arrays to facilitate the beamforming. In some cases, BS 180 may transmit a beamformed signal to UE 104 in one or more transmit directions 182′. UE 104 may receive the beamformed signal from the BS 180 in one or more receive directions 182″. UE 104 may also transmit a beamformed signal to the BS 180 in one or more transmit directions 182″. BS 180 may also receive the beamformed signal from UE 104 in one or more receive directions 182′. BS 180 and UE 104 may then perform beam training to determine the best receive and transmit directions for each of BS 180 and UE 104. Notably, the transmit and receive directions for BS 180 may or may not be the same. Similarly, the transmit and receive directions for UE 104 may or may not be the same.

Wireless communications network 100 further includes a Wi-Fi AP 150 in communication with Wi-Fi stations (STAs) 152 via communications links 154 in, for example, a 2.4 GHz and/or 5 GHz unlicensed frequency spectrum.

Certain UEs 104 may communicate with each other using device-to-device (D2D) communications link 158. D2D communications link 158 may use one or more sidelink channels, such as a physical sidelink broadcast channel (PSBCH), a physical sidelink discovery channel (PSDCH), a physical sidelink shared channel (PSSCH), a physical sidelink control channel (PSCCH), and/or a physical sidelink feedback channel (PSFCH).

EPC 160 may include various functional components, including: a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and/or a Packet Data Network (PDN) Gateway 172, such as in the depicted example. MME 162 may be in communication with a Home Subscriber Server (HSS) 174. MME 162 is the control node that processes the signaling between the UEs 104 and the EPC 160. Generally, MME 162 provides bearer and connection management.

Generally, user Internet protocol (IP) packets are transferred through Serving Gateway 166, which itself is connected to PDN Gateway 172. PDN Gateway 172 provides UE IP address allocation as well as other functions. PDN Gateway 172 and the BM-SC 170 are connected to IP Services 176, which may include, for example, the Internet, an intranet, an IP Multimedia Subsystem (IMS), a Packet Switched (PS) streaming service, and/or other IP services.

BM-SC 170 may provide functions for MBMS user service provisioning and delivery. BM-SC 170 may serve as an entry point for content provider MBMS transmission, may be used to authorize and initiate MBMS Bearer Services within a public land mobile network (PLMN), and/or may be used to schedule MBMS transmissions. MBMS Gateway 168 may be used to distribute MBMS traffic to the BSs 102 belonging to a Multicast Broadcast Single Frequency Network (MBSFN) area broadcasting a particular service, and/or may be responsible for session management (start/stop) and for collecting eMBMS related charging information.

5GC 190 may include various functional components, including: an Access and Mobility Management Function (AMF) 192, other AMFs 193, a Session Management Function (SMF) 194, and a User Plane Function (UPF) 195. AMF 192 may be in communication with Unified Data Management (UDM) 196.

AMF 192 is a control node that processes signaling between UEs 104 and 5GC 190. AMF 192 provides, for example, quality of service (QoS) flow and session management.

Internet protocol (IP) packets are transferred through UPF 195, which is connected to the IP Services 197, and which provides UE IP address allocation as well as other functions for 5GC 190. IP Services 197 may include, for example, the Internet, an intranet, an IMS, a PS streaming service, and/or other IP services.

In various aspects, a network entity or network node can be implemented as an aggregated base station, as a disaggregated base station, a component of a base station, an integrated access and backhaul (IAB) node, a relay node, a sidelink node, to name a few examples.

FIG. 2 depicts an example disaggregated base station 200 architecture. The disaggregated base station 200 architecture may include one or more central units (CUs) 210 that can communicate directly with a core network 220 via a backhaul link, or indirectly with the core network 220 through one or more disaggregated base station units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUs) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUs 210, the DUs 230, the RUs 240, as well as the Near-RT RICs 225, the Non-RT RICs 215 and the SMO Framework 205, may include one or more interfaces or be coupled to one or more interfaces configured to receive or transmit signals, data, or information (collectively, signals) via a wired or wireless transmission medium. Each of the units, or an associated processor or controller providing instructions to the communications interfaces of the units, can be configured to communicate with one or more of the other units via the transmission medium. For example, the units can include a wired interface configured to receive or transmit signals over a wired transmission medium to one or more of the other units. Additionally or alternatively, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (e.g., Central Unit-User Plane (CU-UP)), control plane functionality (e.g., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the E1 interface when implemented in an O-RAN configuration. The CU 210 can be implemented to communicate with the DU 230, as necessary, for network control and signaling.

The DU 230 may correspond to a logical unit that includes one or more base station functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3^{rd} Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communications with one or more UEs 104. In some implementations, real-time and non-real-time aspects of control and user plane communications with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUs 240 and Near-RT RICs 225. In some implementations, the SMO Framework 205 can communicate with a hardware aspect of a 4G RAN, such as an open eNB (O-eNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via 01) or via creation of RAN management policies (such as A1 policies).

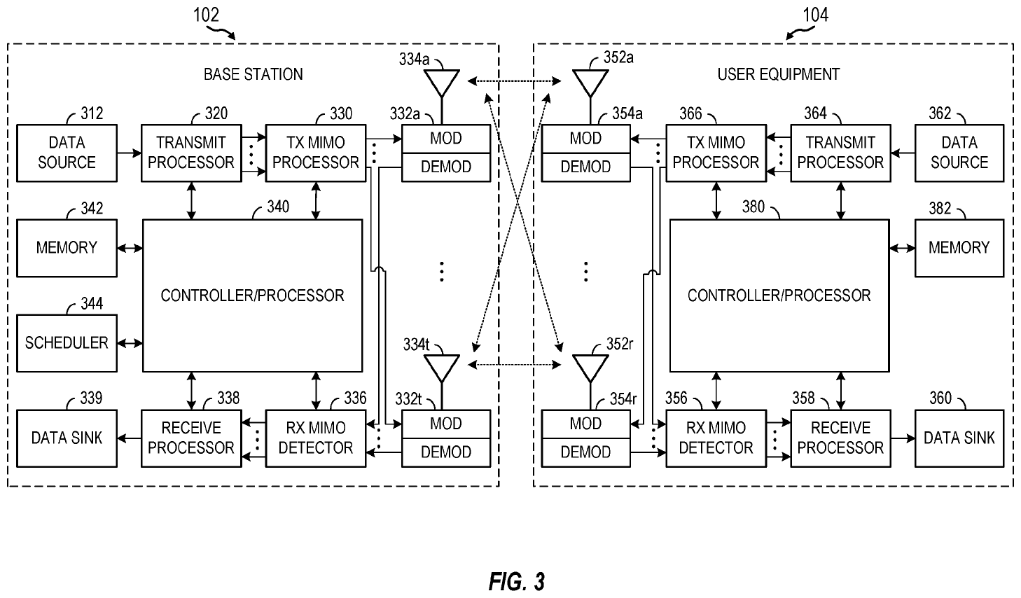

FIG. 3 depicts aspects of an example BS 102 and a UE 104.

Generally, BS 102 includes various processors (e.g., 320, 330, 338, and 340), antennas 334a-t (collectively 334), transceivers 332a-t (collectively 332), which include modulators and demodulators, and other aspects, which enable wireless transmission of data (e.g., data source 312) and wireless reception of data (e.g., data sink 339). For example, BS 102 may send and receive data between BS 102 and UE 104. BS 102 includes controller/processor 340, which may be configured to implement various functions described herein related to wireless communications.

Generally, UE 104 includes various processors (e.g., 358, 364, 366, and 380), antennas 352a-r (collectively 352), transceivers 354a-r (collectively 354), which include modulators and demodulators, and other aspects, which enable wireless transmission of data (e.g., retrieved from data source 362) and wireless reception of data (e.g., provided to data sink 360). UE 104 includes controller/processor 380, which may be configured to implement various functions described herein related to wireless communications.

In regards to an example downlink transmission, BS 102 includes a transmit processor 320 that may receive data from a data source 312 and control information from a controller/processor 340. The control information may be for the physical broadcast channel (PBCH), physical control format indicator channel (PCFICH), physical HARQ indicator channel (PHICH), physical downlink control channel (PDCCH), group common PDCCH (GC PDCCH), and/or others. The data may be for the physical downlink shared channel (PDSCH), in some examples.

Transmit processor 320 may process (e.g., encode and symbol map) the data and control information to obtain data symbols and control symbols, respectively. Transmit processor 320 may also generate reference symbols, such as for the primary synchronization signal (PSS), secondary synchronization signal (SSS), PBCH demodulation reference signal (DMRS), and channel state information reference signal (CSI-RS).

Transmit (TX) multiple-input multiple-output (MIMO) processor 330 may perform spatial processing (e.g., precoding) on the data symbols, the control symbols, and/or the reference symbols, if applicable, and may provide output symbol streams to the modulators (MODs) in transceivers 332a-332t. Each modulator in transceivers 332a-332t may process a respective output symbol stream to obtain an output sample stream. Each modulator may further process (e.g., convert to analog, amplify, filter, and upconvert) the output sample stream to obtain a downlink signal. Downlink signals from the modulators in transceivers 332a-332t may be transmitted via the antennas 334a-334t, respectively.

In order to receive the downlink transmission, UE 104 includes antennas 352a-352r that may receive the downlink signals from the BS 102 and may provide received signals to the demodulators (DEMODs) in transceivers 354a-354r, respectively. Each demodulator in transceivers 354a-354r may condition (e.g., filter, amplify, downconvert, and digitize) a respective received signal to obtain input samples. Each demodulator may further process the input samples to obtain received symbols.

MIMO detector 356 may obtain received symbols from all the demodulators in transceivers 354a-354r, perform MIMO detection on the received symbols if applicable, and provide detected symbols. Receive processor 358 may process (e.g., demodulate, deinterleave, and decode) the detected symbols, provide decoded data for the UE 104 to a data sink 360, and provide decoded control information to a controller/processor 380.

In regards to an example uplink transmission, UE 104 further includes a transmit processor 364 that may receive and process data (e.g., for the PUSCH) from a data source 362 and control information (e.g., for the physical uplink control channel (PUCCH)) from the controller/processor 380. Transmit processor 364 may also generate reference symbols for a reference signal (e.g., for the sounding reference signal (SRS)). The symbols from the transmit processor 364 may be precoded by a TX MIMO processor 366 if applicable, further processed by the modulators in transceivers 354a-354r (e.g., for SC-FDM), and transmitted to BS 102.

At BS 102, the uplink signals from UE 104 may be received by antennas 334a-t, processed by the demodulators in transceivers 332a-332t, detected by a MIMO detector 336 if applicable, and further processed by a receive processor 338 to obtain decoded data and control information sent by UE 104. Receive processor 338 may provide the decoded data to a data sink 339 and the decoded control information to the controller/processor 340.

Memories 342 and 382 may store data and program codes for BS 102 and UE 104, respectively.

Scheduler 344 may schedule UEs for data transmission on the downlink and/or uplink.

In various aspects, BS 102 may be described as transmitting and receiving various types of data associated with the methods described herein. In these contexts, “transmitting” may refer to various mechanisms of outputting data, such as outputting data from data source 312, scheduler 344, memory 342, transmit processor 320, controller/processor 340, TX MIMO processor 330, transceivers 332a-t, antenna 334a-t, and/or other aspects described herein. Similarly, “receiving” may refer to various mechanisms of obtaining data, such as obtaining data from antennas 334a-t, transceivers 332a-t, RX MIMO detector 336, controller/processor 340, receive processor 338, scheduler 344, memory 342, and/or other aspects described herein.

In various aspects, UE 104 may likewise be described as transmitting and receiving various types of data associated with the methods described herein. In these contexts, “transmitting” may refer to various mechanisms of outputting data, such as outputting data from data source 362, memory 382, transmit processor 364, controller/processor 380, TX MIMO processor 366, transceivers 354a-t, antenna 352a-t, and/or other aspects described herein. Similarly, “receiving” may refer to various mechanisms of obtaining data, such as obtaining data from antennas 352a-t, transceivers 354a-t, RX MIMO detector 356, controller/processor 380, receive processor 358, memory 382, and/or other aspects described herein.

In some aspects, a processor may be configured to perform various operations, such as those associated with the methods described herein, and transmit (output) to or receive (obtain) data from another interface that is configured to transmit or receive, respectively, the data.

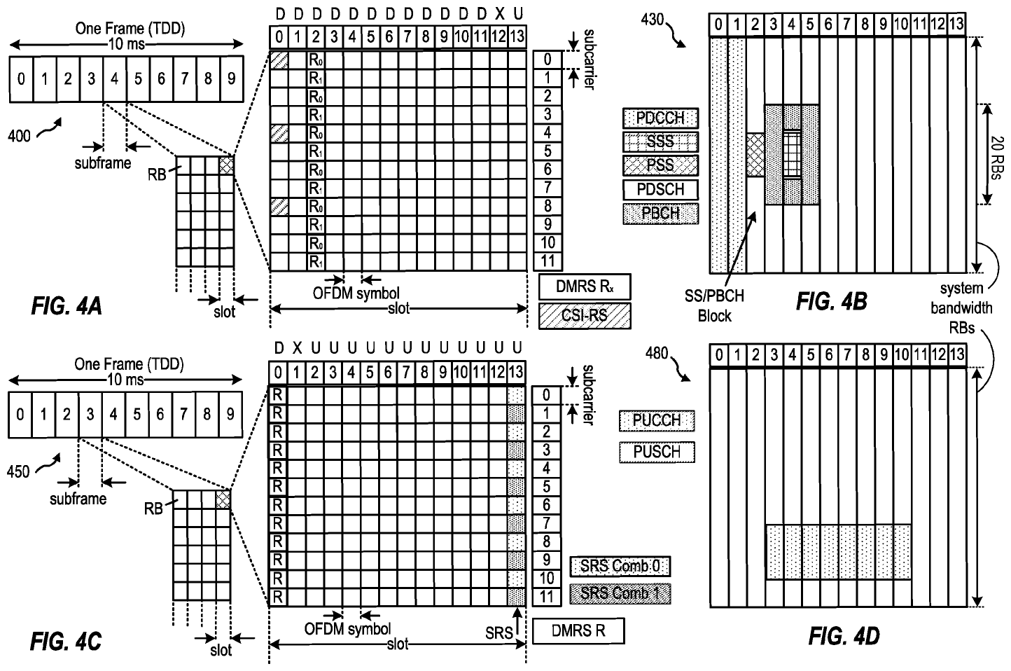

FIGS. 4A, 4B, 4C, and 4D depict aspects of data structures for a wireless communications network, such as wireless communications network 100 of FIG. 1.

In particular, FIG. 4A is a diagram 400 illustrating an example of a first subframe within a 5G (e.g., 5G NR) frame structure, FIG. 4B is a diagram 430 illustrating an example of DL channels within a 5G subframe, FIG. 4C is a diagram 450 illustrating an example of a second subframe within a 5G frame structure, and FIG. 4D is a diagram 480 illustrating an example of UL channels within a 5G subframe.

Wireless communications systems may utilize orthogonal frequency division multiplexing (OFDM) with a cyclic prefix (CP) on the uplink and downlink. Such systems may also support half-duplex operation using time division duplexing (TDD). OFDM and single-carrier frequency division multiplexing (SC-FDM) partition the system bandwidth (e.g., as depicted in FIGS. 4B and 4D) into multiple orthogonal subcarriers. Each subcarrier may be modulated with data. Modulation symbols may be sent in the frequency domain with OFDM and/or in the time domain with SC-FDM.

A wireless communications frame structure may be frequency division duplex (FDD), in which, for a particular set of subcarriers, subframes within the set of subcarriers are dedicated for either DL or UL. Wireless communications frame structures may also be time division duplex (TDD), in which, for a particular set of subcarriers, subframes within the set of subcarriers are dedicated for both DL and UL.

In FIGS. 4A and 4C, the wireless communications frame structure is TDD where D is DL, U is UL, and X is flexible for use between DL/UL. UEs may be configured with a slot format through a received slot format indicator (SFI) (dynamically through DL control information (DCI), or semi-statically/statically through radio resource control (RRC) signaling). In the depicted examples, a 10 ms frame is divided into 10 equally sized 1 ms subframes. Each subframe may include one or more time slots. In some examples, each slot may include 7 or 14 symbols, depending on the slot format. Subframes may also include mini-slots, which generally have fewer symbols than an entire slot. Other wireless communications technologies may have a different frame structure and/or different channels.

In certain aspects, the number of slots within a subframe is based on a slot configuration and a numerology. For example, for slot configuration 0, different numerologies (μ) 0 to 5 allow for 1, 2, 4, 8, 16, and 32 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2μ slots/subframe. The subcarrier spacing and symbol length/duration are a function of the numerology. The subcarrier spacing may be equal to 2×15 kHz, where is the numerology 0 to 5. As such, the numerology μ=0 has a subcarrier spacing of 15 kHz and the numerology μ=5 has a subcarrier spacing of 480 kHz. The symbol length/duration is inversely related to the subcarrier spacing. FIGS. 4A, 4B, 4C, and 4D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 s.

As depicted in FIGS. 4A, 4B, 4C, and 4D, a resource grid may be used to represent the frame structure. Each time slot includes a resource block (RB) (also referred to as physical RBs (PRBs)) that extends, for example, 12 consecutive subcarriers. The resource grid is divided into multiple resource elements (REs). The number of bits carried by each RE depends on the modulation scheme.

As illustrated in FIG. 4A, some of the REs carry reference (pilot) signals (RS) for a UE (e.g., UE 104 of FIGS. 1 and 3). The RS may include demodulation RS (DMRS) and/or channel state information reference signals (CSI-RS) for channel estimation at the UE. The RS may also include beam measurement RS (BRS), beam refinement RS (BRRS), and/or phase tracking RS (PT-RS).

FIG. 4B illustrates an example of various DL channels within a subframe of a frame. The physical downlink control channel (PDCCH) carries DCI within one or more control channel elements (CCEs), each CCE including, for example, nine RE groups (REGs), each REG including, for example, four consecutive REs in an OFDM symbol.

A primary synchronization signal (PSS) may be within symbol 2 of particular subframes of a frame. The PSS is used by a UE (e.g., 104 of FIGS. 1 and 3) to determine subframe/symbol timing and a physical layer identity.

A secondary synchronization signal (SSS) may be within symbol 4 of particular subframes of a frame. The SSS is used by a UE to determine a physical layer cell identity group number and radio frame timing.

Based on the physical layer identity and the physical layer cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block. The MIB provides a number of RBs in the system bandwidth and a system frame number (SFN). The physical downlink shared channel (PDSCH) carries user data, broadcast system information not transmitted through the PBCH such as system information blocks (SIBs), and/or paging messages.

As illustrated in FIG. 4C, some of the REs carry DMRS (indicated as R for one particular configuration, but other DMRS configurations are possible) for channel estimation at the base station. The UE may transmit DMRS for the PUCCH and DMRS for the PUSCH. The PUSCH DMRS may be transmitted, for example, in the first one or two symbols of the PUSCH. The PUCCH DMRS may be transmitted in different configurations depending on whether short or long PUCCHs are transmitted and depending on the particular PUCCH format used. UE 104 may transmit sounding reference signals (SRS). The SRS may be transmitted, for example, in the last symbol of a subframe. The SRS may have a comb structure, and a UE may transmit SRS on one of the combs. The SRS may be used by a base station for channel quality estimation to enable frequency-dependent scheduling on the UL.

FIG. 4D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

### Introduction to Polar Codes

Polar codes are a relatively recent breakthrough in coding theory which have been proven to asymptotically (for code size N approaching infinity) achieve the Shannon capacity. Polar codes have many desirable properties such as deterministic construction (e.g., based on a fast Hadamard transform), very low and predictable error floors, and simple successive-cancellation (SC) based decoding. They are currently being considered as a candidate for error-correction in next-generation wireless systems such as NR.

Polar codes are linear block codes of length N=2ⁿ where their generator matrix is constructed using the n^{th} Kronecker power of the matrix

$$G = ( \begin{matrix}1 & 0 \\ 1 & 1\end{matrix} ) ,$$

denoted by Gⁿ. For example, Equation 1 shows the resulting generator matrix for n=3.

$${G}^{⊗ 3} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] \qquad ( 1 )$$

According to certain aspects, a codeword may be generated (e.g., by encoder 706) by using the generator matrix to encode a number of input bits consisting of K information bits and N−K “frozen” bits which contain no information and are “frozen” to a known value, such as zero. For example, given a number of input bits u=(u₀, u₁, . . . , u_{N-1}), a resulting codeword vector x=(x₀, x₁, . . . , x_{N-1}) may be generated by encoding the input bits using the generator matrix G. This resulting codeword may then be rate matched and transmitted by a base station over a wireless medium and received by a UE.

When the received vectors are decoded, for example by using a Successive Cancellation (SC) decoder (e.g., decoder 816), every estimated bit, ûᵢ, has a predetermined error probability given that bits u₀ⁱ⁻¹ were correctly decoded, that, for an extremely large codesize N, tends towards either 0 or 0.5. Moreover, the proportion of estimated bits with a low error probability tends towards the capacity of the underlying channel. Polar codes exploit this phenomenon, called channel polarization, by using the most reliable K bits to transmit information, while setting to a predetermined value (such as 0), also referred to as freezing, the remaining (N−K) bits, for example as explained below.

Polar codes transform the channel into N parallel “virtual” channels for the N information and frozen bits. If C is the capacity of the channel, then, for sufficiently large values of N, there are almost N*C channels which are extremely reliable and there are almost N(1−C) channels which are extremely unreliable. The basic polar coding scheme then involves freezing (i.e., setting to a known value, such as zero) the input bits in u corresponding to the unreliable channels, while placing information bits only in the bits of u corresponding to reliable channels. For short-to-medium N, this polarization may not be complete in the sense there could be several channels which are neither completely unreliable nor completely reliable (i.e., channels that are marginally reliable). Depending on the rate of transmission, bits corresponding to these marginally reliable channels may be either frozen or used for information bits.

### Introduction to Probabilistic Amplitude Shaping

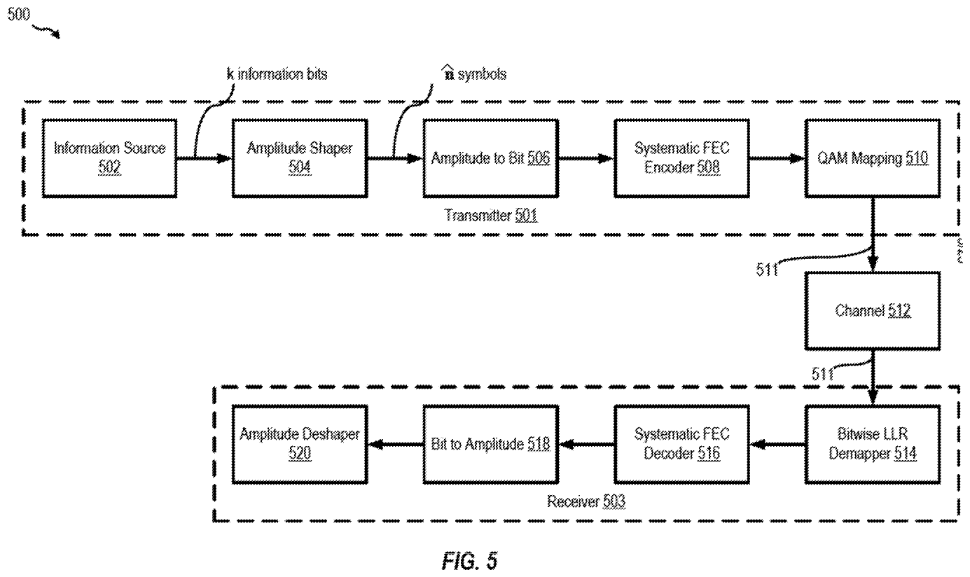

FIG. 5 illustrates a communication system employing probabilistic amplitude shaping. Probabilistic amplitude shaping (PAS) utilizes reverse concatenation whereby the shaping precedes FEC coding.

The communication system 500 includes a wireless transmitter 501 and a wireless receiver 503. For example, an information source 502 may generate k information bits that is received by an amplitude shaper 504. The amplitude shaper 504 may generate a sequence of symbols (e.g., n symbols in a fixed-to-fixed scheme or \hat{n} symbols in a variable-to-fixed scheme). The sequence of symbols (n symbols or \hat{n} symbols) may be received by an amplitude to bit component 506 and then an FEC encoder 508 to produce a set of bits. In some examples, some of the bits are shaped and others are uniformly distributed. After the encoding, the bits are mapped, e.g., to quadrature amplitude modulation (QAM) symbols by a QAM mapping component 510. A signal 511 (e.g., the symbols) is then transmitted over the wireless medium to the wireless receiver 503, e.g., over a channel 512.

At the wireless receiver 503, the signal 511 is received by a bitwise log-likelihood ratios (LLR) demapper component 514 to demap the symbols of the signal 511. The demapped symbols are received by the FEC decoder 516 and then a bit to amplitude component 518 to decode the bits. The decoded bits are provided to an amplitude deshaper 520 to distribute the received bits (e.g., uniformly), which may then be sent to their destination.

Amplitude shaper 504 can also be known as or an implementation of a distribution matcher. In some aspects, a distribution matcher includes a decompressor (e.g., a decoder) to convert a sequence of information bits (u) into a set of symbols. The sequence of information bits (u) may be uniformly distributed. In an example, in 5G NR, the sequence of information bits may be uniformly distributed. The decompressor may generate the sequence of symbols based on a target probability mass function (PMF), such as a Maxwell-Boltzmann Distribution, and a symbol block length (n). The sequence of symbols may be transmitted to a receiver for processing to determine the transmitted information.

The distribution matcher may also include a compressor (e.g., an encoder) to convert the set of symbols into a sequence of compressed information bits (û). In a fixed-to-fixed scheme, the distribution matcher may include a comparator to compare the sequence of information bits (u) to the sequence of compressed information bits (û) to determine how many information bits were not converted into the set of symbols. In some examples, the distribution matcher may provide the output of the comparator to the receiver so that the receiver can determine how to process the set of symbols. For example, based on a compressor at the receiver, the receiver may compress the set of symbols to generate information bits based on the target PMF, which may result in extra bits. The receiver may use the output of the comparator (e.g., discard signaling) to determine how many bits to discard.

Alternatively, the distribution matcher may employ a variable-to-fixed scheme in which the decompressor is configured with a “back-off” limit. The back-off limit may limit the amount of information bits that the decompressor may convert to the set of symbols so that extra bits are not transmitted to the receiver for discarding. Moreover, the variable-to-fixed scheme may limit the amount of overhead (e.g., compared to the fixed-to-fixed scheme) as a comparator is not needed and, thus, the distribution matcher may forego transmitting discard signaling with information about the number of bits to discard at the receiver. In such examples, when employing the variable-to-fixed scheme, the rate loss compared to target entropy may be improved compared to when employing the fixed-to-fixed scheme.

### Aspects Related to Polar Code Construction and Configuration for Block-Code-Based Shaping

Probabilistic amplitude shaping (PAS), as described above, involves generating amplitudes of pulse amplitude modulation (PAM) symbols using a distribution matcher (DM). Thereafter, a subsequent systematic FEC encoder generates signs for the PAM symbols based on the amplitudes. In some cases, a goal of PAS is to minimize an average signal power of a transmitted signal. In some cases, to minimize the average signal power of a transmitted signal, a bit sequence of the transmitted signal may be modified. In some cases, modifying the bit sequence of the transmitted signal may involve applying a bit-mask to a most significant bit (MSB) of the bit sequence to lower the average signal power of the transmitted signal. For example, a bit-level and symbol transmit power may have a certain relationship in which a first bit (e.g., b0) (excluding a sign bit) may control the transmit power of a symbol ‘s’ of the transmitted signal (e.g., assuming gray mapping) than other bits. As a result, if bit b0 is transmitted with a bit value of 0 (zero), then the transmit power associated with symbol ‘s’ of the transmitted signal may be lower as compared to a bit value of 1 (one) (e.g., (‘1’, ‘9’), vs. (‘25’, ‘49’)), as shown in the Table 1 below.

TABLE 1

| s | −7 | −5 | −3 | −1 | 1 | 3 | 5 | 7 |
|---|---|---|---|---|---|---|---|---|
| sign | 0 | 0 | 0 | 0 | 1 | 1 | 1 | 1 |
| b0 | 0 | 0 | 1 | 1 | 1 | 1 | 0 | 0 |
| b1 | 0 | 1 | 1 | 0 | 0 | 1 | 1 | 0 |
| TxPower(s\hat{ }2) | 49 | 25 | 9 | 1 | 1 | 9 | 25 | 49 |

In some cases, to perform the probabilistic amplitude shaping and the bit-masking of certain bits of a transmitted signal, a transmitter may first identify a set of information bits for transmission. Thereafter, the transmitter may use a shaping encoder to mask the set of information bits based on a sequence of shaping bits (K) to generate a sequence of shaped information bits. Thereafter, the transmitter may encode the sequence of shaping bits and sequence of shaped information bits to generate a set of encoded bits. After the encoding, the set of encoded bits are mapped to, for example, a sequence of shaped symbols (e.g., QAM symbol) and transmitted in a signal over a wireless medium to a receiver.

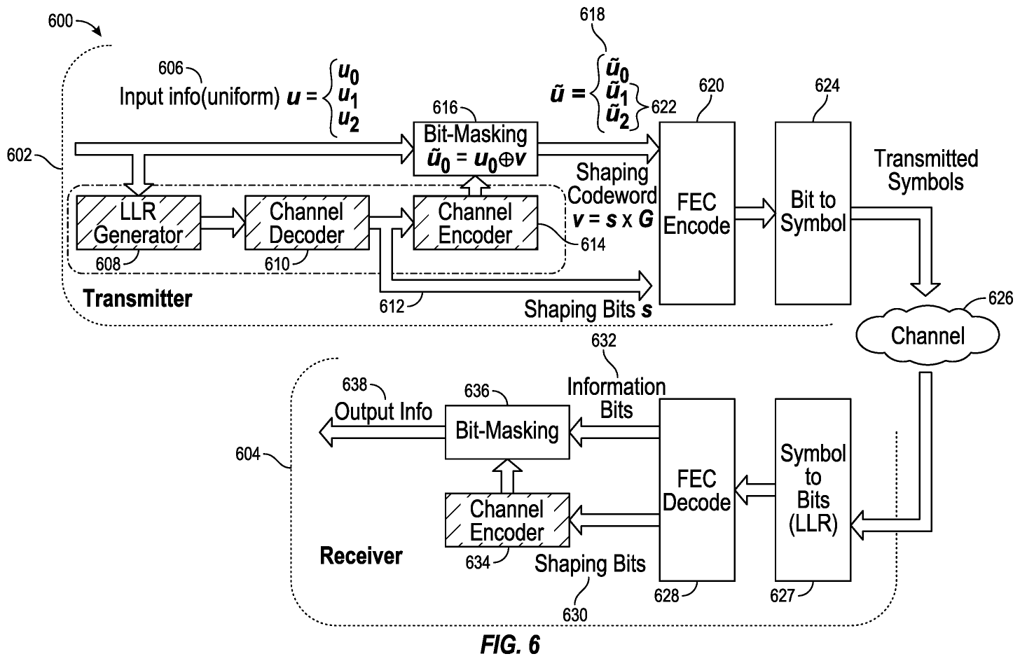

At the receiver, the signal is received by a bitwise LLR demapper component which is configured to demap the sequence of symbols of the signal. In some cases, demapping the sequence of symbols may be based on symbol probabilities associated with the QAM symbols. Thereafter, the demapped sequence of symbols may then be jointly decoded by an FEC decoder to obtain the sequence of shaping bits and sequence of shaped information bits. Thereafter, the receiver may then re-encode the decoded shaped information bits to obtain the original set of information bits. Additional details of this process are described with respect to FIG. 6, below.

In some cases, the sequence of shaping bits may be generated by based on a block code, such as a Polar code. Polar codes have been used for channel coding for control channel transmissions in 5G NR. Another good feature that Polar codes provide is that they can achieve a “rate-distortion” bound for lossy data compression. As such, it may be beneficial to use Polar codes for bit-level shaping with block codes in order to provide good data compression. As noted above, Polar codes are linear block codes defined by (N, K) where N=2ⁿ and is the block length and K is the shaping bit length. Accordingly, the block length N and information bit length K may need to be taken into account when constructing and using Polar codes for block-code-based probabilistic amplitude shaping. For example, in some cases, if too large of an N is used when constructing a Polar code, Polar decoding at the receiver may be too complex and may take too long, resulting in an increase consumption of processing resources and power consumption, as well as poor user experience. Additionally, because K controls the number of shaping bits used to perform probabilistic amplitude shaping, selecting too low of a number for K results in less shaping and poorer shaping performance.

Accordingly, aspects of the present disclosure provide techniques for Polar code construction and configuration for block-code-based shaping. More specifically, for example, aspects of the present disclosure provide techniques for constructing Polar codes that may be used to perform probabilistic amplitude shaping on a set of information bits for transmission. Additionally, because symbol probabilities are taken into account when demapping/demodulating received symbols, aspects of the present disclosure provide techniques for indicating to a receiver device these symbol probabilities.

FIG. 6 illustrates a communication system 600, including a transmitter 602 and a receiver 604, employing probabilistic amplitude shaping based on a block code, such as a Polar code. In some cases, the transmitter 602 may be an example of a network entity, such as the BS 102 described with respect to FIGS. 1 and 3 or a disaggregated BS as described with respect to FIG. 2. In some cases, the receiver 604 may be an example of a user equipment, such as the UE 104 described with respect to FIGS. 1 and 3. In other cases, the transmitter 602 may be an example of the UE 104 while the receiver 604 may be an example of the BS 102 or a disaggregated BS.

As shown, the transmitter 602 may identify a set of information bits 606 for transmission. In some cases, the set of information bits 606 may be uniformly distributed and may correspond to a bit-level sequence of amplitude symbols u=u₀, u₁, u₂, . . . , uₘ₋₁, where m is the log 2 of modulation order of the corresponding 1-dimentional QAM. For example, assuming 64-QAM is configured, each dimension is 8-PAM, and the number of bits carried is thus m=log₂(8)=3, and u u₀, u₁, u₂. The set of information bits 606 may be input into an LLR generator 608 of the transmitter 602. The LLR generator 608 is configured to generate a set of LLRs corresponding to the set of information bits 606 and to segment the set of LLRs into a plurality of shaping blocks based, at least in part, on a shaping block length for the plurality of shaping blocks.

In some cases, a goal of probabilistic amplitude shaping is to generate a cover code that maximizes power savings after bit-masking. As such, the LLR generator 608 may be configured to generate LLRs for the set of information bits 606 according to how much power is saved by bit flipping. For example, assuming that (u₀, u₁) in the sequence of amplitude symbols u corresponding to the set of information bits 606 are equal to (1,1), flipping (e.g., masking) u₀ such that (ū₀, u₁)=(0,1), the associated power change is ‘16’. In such cases, the relative LLR may be marked as ‘16’. Table 2, below, illustrates the example of flipping u₀ and associated LLR and power savings.

TABLE 2

| Symbol Index | 1 | 2 | 3 | 4 | 5 | 6 |
|---|---|---|---|---|---|---|
| u₀ | 0 | 1 | 1 | 0 | 1 | 0 |
| u₁ | 1 | 1 | 0 | 1 | 0 | 0 |
| Tx symbol(Gray | 5 | 3 | 1 | 5 | 1 | 7 |
| mapping) | | | | | | |
| Tx power(original) | 25 | 9 | 1 | 25 | 1 | 49 |
| Tx symbol w/ | 3 | 5 | 7 | 3 | 7 | 1 |
| flipping u₀ | | | | | | |
| Tx power w/ | 9 | 25 | 49 | 9 | 49 | 1 |
| flipping u₀ | | | | | | |
| LLR = Tx | −16 | 16 | 48 | −16 | 48 | −48 |
| Power(flip) − Tx | | | | | | |
| Power(original) | | | | | | |

In some cases, segmenting the LLRs into the plurality of shaping blocks may be based on one or more parameters. For example, the one or more parameters may include a number of shaping blocks (Cₛ), which may be defined as Cₛ=┌2Nᵣₑ/Nₛₘₐₓ┐, where Nᵣₑ is a number of resource elements (REs) available for transmitting the set of information bits 606 and Nₛₘₐₓ is a maximum shaping block length. In some cases, Nₛₘₐₓ may be a fixed value in a wireless communications standard, such as 512 (e.g., 2⁹). A shaping block length (N_{S}) may be defined as Nₛ=┌2Nᵣₑ/Cₛ┐. If an LLR length N_{LLR} or input symbol length Nᵢₙ (e.g., which may be defined as N_{LLR}=Nᵢₙ=2Nᵣₑ) is larger than the shaping block length (Nₛ), then multiple shaping blocks may be obtained via segmentation. In some cases, segmenting the LLRs into the plurality of shaping blocks may depend on a subband over which the set of information bits are to be transmitted and may be different for different subbands.

Once the set of LLRs have been segmented into the plurality of shaping blocks, the plurality of shaping blocks may be sent to a channel decoder 610. The channel decoder 610 is configured to decode the plurality of shaping blocks using a Polar code to obtain a sequence of shaping bits 612 (s). In some cases, the channel decoder 610 may be configured to decode the plurality of shaping blocks according to a shaping code rate (Rₛ), which may be defined as Rₛ=Kₛ/Nₛ, where Kₛ is a size of the shaping bits 612 (s). In some cases, the shaping code rate (Rₛ) may depend on a subband over which the set of information bits are to be transmitted and may be different for different subbands. In some cases, the Polar code may depend on the shaping code rate Rₛ and the shaping block length Nₛ. More specifically, for example, a generator matrix (G) for the Polar code may be constructed based on the shaping code rate Rₛ and the shaping block length Nₛ. In some cases, the Polar code may use a 5G NR Polar sequence or may use a polarization weight (PW) sequence.

In some cases, the shaping block length (N_{S}) should be as large as possible since large shaping block lengths will asymptotically achieve the ‘rate distortion bound.’ However, larger shaping block lengths may create problems for Polar code decoding, such as concerns on decoding complexity (N_{S}*log₂(N_{S})) and latency. Regarding the size of the shaping bits 612 (e.g., Kₛ), a large value for Kₛ gives better shaping performance, but adds to overhead and reduces the amount of useful data that may be transmitted. As such, a tradeoff between the number of shaping bits Kₛ and overall performance exists, which may be similar to the distribution matching (DM) in which a particular distribution is targeted (e.g., constant composition distribution matching) or a minimal transmit power is targeted (e.g., sphere shaping). As such, it may be advantageous to limit the number of shaping bits (Kₛ) based a signal to noise ratio (SNR) of a wireless channel over which the set of information bits are to be transmitted (e.g., wireless channel 626).

After being generated, the sequence of shaping bits 612 may be input into a channel encoder 614. The channel encoder 614 may be configured to (re)encode, according to the shaping code rate, the sequence of shaping bits 612 using the Polar code to obtain a shaping codeword (v). For example, to obtain the shaping codeword v, the channel encoder 614 may multiply the sequence of shaping bits 612 (s) by a generator matrix (G) of the Polar code according to v=s×G. Thereafter, a bit-masking component 616 of the transmitter 602 may be configured to perform a shaping operation on a subset of the set of information bits 606 to generate a sequence of shaped information bits 618. As noted above, a goal of shaping is to maximize power savings. Accordingly, to maximize power savings, the bit-masking component 616 may be configured to apply the shaping codeword onto bit-level of amplitude symbols that have the highest impact on signal power (e.g., MSB of u₀). For example, bit-masking component 616 may perform the shaping operation on an MSB and apply the shaping codeword v according to [symbol] =u₀ ⊕v, where ⊕ denotes element-wise modulo-2 addition. In some cases, performing the shaping operation may depend on a subband over which the set of information bits are to be transmitted and may be different for different subbands.

After perform the shaping operation, the sequence of shaped information bits 618 (e.g., [symbol] ), a remaining subset of non-shaped information bits of the set of information bits (e.g., u₁, u₂, . . . ), and the sequence of shaping bits 612 (s) may be input into a systematic FEC encoder 620. The FEC encoder 620 may then encode the sequence of shaped information bits 618 (e.g., [symbol] ), a remaining subset of non-shaped information bits of the set of information bits 622 (e.g., u₁, u₂, . . . ), and the sequence of shaping bits 612 (s) using an FEC code rate to obtain a set of encoded bits in the plurality of shaping blocks. In some cases, the FEC code rate may be specified by a modulation and coding scheme (MCS), which may be indicated using an MCS table.

After encoding, the set of encoded bits in the plurality of shaping blocks may be sent to a bit-to-symbol mapper 624. The bit-to-symbol mapper 624 is configured to map the encoded bits to symbols (QAM symbols) to generate a sequence of shaped symbols from or based on the sequence of shaping bits. Thereafter, the sequence of shaped symbols may be transmitted to the receiver 604 over a wireless channel 626.

At the receiver 604, the sequence of shaped symbols may be received by a symbol-to-bit demapper 627, which is configured to demap the sequence of shaped symbols to generate a sequence of bit-level LLRs corresponding to the set of encoded bits described above. In some cases, demapping the sequence of symbols may be based on symbol probabilities associated with the sequence of shaped symbols. For example, in some cases, the receiver 604 may receive the sequence of shaped symbols and may use the symbol probabilities to perform maximum a posteriori probability (MAP) demodulation to convert the received sequence of symbols to the bit-level LLRs of the set of encoded bits.

Thereafter, the bit-level LLRs corresponding to the set of encoded bits may then be jointly decoded by an FEC decoder 628 to obtain a sequence of shaping bits 630 (e.g., the sequence of shaping bits 612 generated by the transmitter 602) and a sequence of information bits 632. The sequence of information bits may include a sequence of shaped information bits (e.g., sequence of shaped information bits 618) as well as a remaining subset of non-shaped information bits (e.g., the remaining subset of non-shaped information bits of the set of information bits 622).

Thereafter, the sequence of shaping bits 630 may be input into a channel encoder 634. The channel encoder 634 may be configured to encode the sequence of shaping bits 630 (e.g., using a Polar code) according to a shaping code rate to generate a deshaping codeword.

Thereafter, the deshaping codeword as well as the sequence of information bits 632 may be input into a bit-masking component 636. The bit-masking component 636 may be configured to perform a deshaping operation on the sequence of shaped information bits in the sequence of information bits 632. For example, in some cases, the bit-masking component 636 may apply the deshaping codeword to the sequence of shaped information bits to deshape the sequence of shaped information bits and obtain a sequence of deshaped information bits. Thereafter, the receiver 604 may concatenate the sequence of deshaped information bits with the remaining subset of non-shaped information bits to obtain a set of information bits 638 corresponding to the set of information bits 606 of the transmitter 602.

As noted above, the symbol-to-bit demapper 627 of the receiver 604 may demap the sequence of symbols received from the transmitter 602 may be based on symbol probabilities. Additionally, in order to properly decode the bit-level LLRs corresponding to the set of encoded bits, the FEC decoder 628 of the receiver 604 may need to decode the bit-level LLRs using the same FEC code rate that was used by the FEC encoder 620 to encode the sequence of shaped information bits 618 (e.g., [symbol] ), the remaining subset of non-shaped information bits of the set of information bits 622 (e.g., u₁, u₂, . . . ), and the sequence of shaping bits 612 (s). Moreover, in order to properly perform the deshaping operation, the channel encoder 634 of the receiver 604 may need to encode the sequence of shaping bits 630 using the same shaping code rate as was used by the channel decoder 610 of the transmitter 602. Accordingly, aspects of the present disclosure provide techniques for indicating to the receiver 604 the symbol probabilities, MCS, and shaping code rate, as explained below.

Regarding the symbol probabilities, a symbol's distribution or probability may be implicitly associated with shaping code configuration. For example, 64 QAM has 8 symbol on each dimension and 4 symbols on the positive side. As such, the probability of symbol |s|=(1, 3, 5, 7) equals (α, β, γ, 1−(α+β+γ)), where α, β, γ is associated with Nₛ, Kₛ, or Rₛ, or any combinations thereof. Accordingly, symbol probabilities may be pre-calculated via numeric simulations using different combinations of Nₛ, Kₛ, or Rₛ, and therefore may be predetermined or associated with MCS. For example, as illustrated in Table 3, below, an MCS table may be defined that associates an MCS index value to a particular modulation order, FEC code rate, shaping code rate, and symbol probability.

TABLE 3

| MCS | | FEC | Shaping | Symbol |
|---|---|---|---|---|
| Index | Order | Code Rate | Code Rate | Probability |
| 8 | 64 | 3/4 | 3/8 | [0.5, 0.3, 0.2] |
| 9 | 64 | 3/4 | 2/8 | [0.45, 0.3, 0.25] |
| 10 | 64 | 4/5 | 2/8 | [0.5, 0.3, 0.2] |
| 11 | 256 | 4/5 | 4/8 | [0.4, 0.3, 0.2, 0.1] |

Accordingly, in some cases, the transmitter 602 may transmit, to the receiver 604, configuration information indicating an MCS index value associated with the sequence of symbols (e.g., including the set of encoded bits). The MCS index value corresponds to an entry in an MCS lookup table, as illustrated in Table 3, which indicates a modulation order associated with the set of encoded bits, an FEC code rate, and a shaping code rate.

In some cases, because each shaped symbol of the sequence of shaped symbols transmitted to the receiver 604 is associated with a respective symbol probability, the transmitter 602 may also provide an indication of each of the respective symbol probabilities to the receiver 604. In some cases, the indication of each of the respective symbol probabilities may be provided by the MCS index value transmitted by the transmitter 602 to the receiver 604. For example, as shown in Table 3, the entry in the MCS lookup table, corresponding to the MCS index value, further indicates each of the respective symbol probabilities. In some cases, the MCS lookup table may be fixed in a wireless communications standard. In such cases, the MCS lookup table specified in the wireless communications standard may include, for each MCS entry/index, an indication of a modulation order, an FEC encoder rate, a shaping code rate, and symbol probabilities after shaping, as shown above in Table 3.

In some cases, different vendors may have different shaping capabilities. For example, each vendor may use different algorithms for Polar decoding, which may result in different shaping performances. As such, it may not be possible to indicate the symbol probabilities in an MCS lookup table common to all vendors since each vendor may have different shaping performances resulting in different symbol probabilities among the vendors. Accordingly, in some cases, providing the indication of each of the respective symbol probabilities comprises transmitting one or more radio resource control (RRC) messages including the indication of each of the respective symbol probabilities.

In such cases, the MCS lookup table may be partially fixed in the wireless communications standard. For example, in such cases, the MCS look up table may include, for each MCS entry/index, an indication of a modulation order, an FEC encoder rate, and a shaping code rate. The shaping probabilities may then be provided via RRC signaling for each entry in the MCS lookup table. In some cases, only the shaping probabilities for 16 QAM and above modulation orders may need to be signaled in the RRC signaling.

As noted above, the parameter Nₛₘₐₓ may be used when segmenting a set of LLRs into the plurality of shaping blocks. In some cases, Nₛₘₐₓ may be different for downlink transmissions (e.g., when the transmitter 602 is a network entity, such as BS 102) as compared to uplink transmissions (e.g., when the transmitter 602 is a user equipment, such as UE 104). For example, in some cases, Nₛₘₐₓ for downlink transmissions may be fixed at 512 while Nₛₘₐₓ for uplink transmissions may be fixed at 256. In some cases, Nₛₘₐₓ may be configured using radio resource control (RRC) signaling. For example, in some cases, the wireless communications standard may specify a plurality of Nₛₘₐₓ (e.g., 128, 256, 512, etc.) and RRC signaling may be used to indicate which value of Nₛₘₐₓ to use. For example, in some cases, the transmitter 602 may transmit RRC signaling to the receiver 604 indicating Nₛₘₐₓ associated with the sequence of shaped symbols. In some cases, when the transmitter 602 comprises a network entity (e.g., BS 102) and the receiver comprises a user equipment (e.g., UE 104), the transmitter 602 may indicate an Nₛₘₐₓ for the receiver 604 (e.g., UE 104) to use processing information for transmission to the transmitter 602 (e.g., BS 102).

In some cases, rate matching (e.g., repetition, shortening, puncturing) is performed when Polar codes are used. However, when Polar codes for shaping are used, only shortening or puncturing may be used and repetition may not be used. In some cases, when the shaping block length (Nₛ) for the plurality of shaping blocks is greater than a first power of two integer (e.g., 2^{m}), puncturing or shortening may not be proper to construct a better sequence of shaped symbols. As such, an alternative approach may include skipping certain symbols when performing the shaping operation described above. An example of skipping symbols when performing the shaping operation is illustrated below in Table 4. For example, as shown in Table 4, symbols 0-2 of bit sequence u₁ may be shaped (e.g., indicated by the bold and underlining) while symbol 3 of bit sequence u₁ may be skipped. Additional details regarding this symbol skipping is explained below.

Symbol index

| | | 0 | 1 | 2 | 3 |
|---|---|---|---|---|---|
| Bit | U0 | U0, 0 | U0, 1 | U0, 2 | U0, 3 |
| Sequence | U1 | U1, 0 | U1, 1 | U1, 2 | U1, 3 |
| | U2 | U2, 0 | U2, 1 | U2, 2 | U2, 3 |

As described above, the shaping operation (e.g., bit-masking) may be performed on an MSB of a symbol. As a result, shaping a “symbol” may be considered equivalent to shaping the MSB. Accordingly, with respect to skipping certain symbols when performing the shaping operation, if 2^{m}<Nₛ<2^{m}(1+δ), where m is the largest value that supports 0<δ<1, then Nₛ=2^{m}, and the number of shaping blocks of shaped symbols is Cₛ=└Nᵢₙ/Nₛ┘, and the remaining subset of non-shaped information bits is then Nᵢₙ−CₛNₛ.

In other words, when the shaping block length for the plurality of shaping blocks is greater than a first power of two integer but less than a second power of two integer (e.g., 2^{m}<Nₛ<2^{m}(1+δ)), the shaping block length (Nₛ) for the plurality of shaping blocks may be reduced the first power of two integer (e.g., 2^{m}). While reducing the shaping block length may reduce some shaping performance, such reduction in the shaping block length may simplify construction of the shaping codeword by the channel encoder 614 of the transmitter 602.

### Example Operations of a Transmitting Device

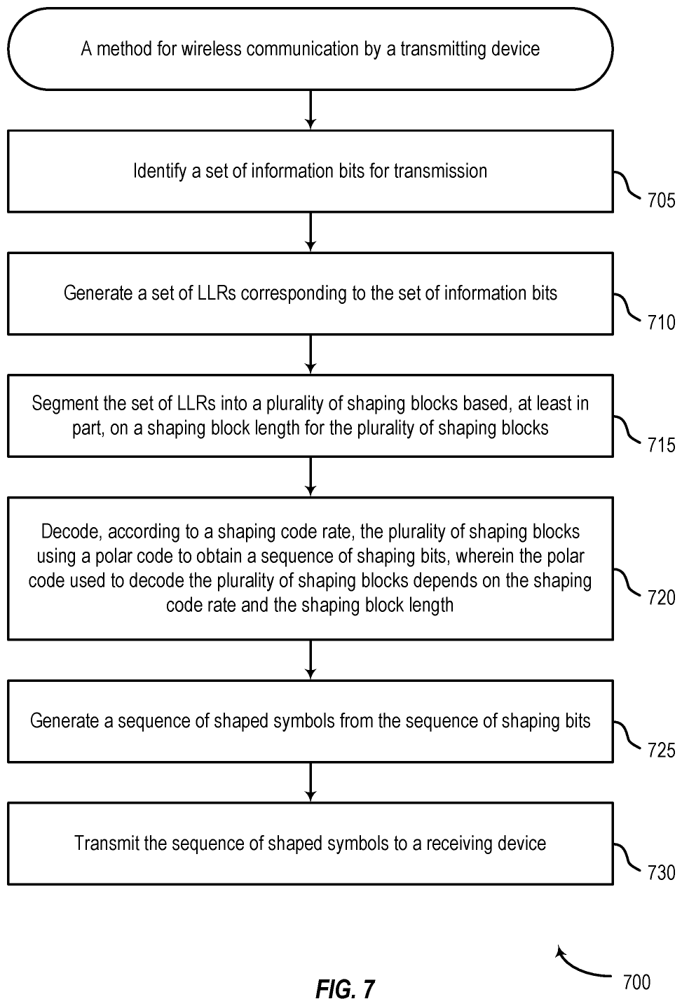

FIG. 7 shows an example of a method 700 for wireless communication by a transmitting device. In some aspects, the transmitting device is a network entity, such as a BS 102 of FIGS. 1 and 3, or a disaggregated base station as discussed with respect to FIG. 2. In some aspects, the transmitting device is a UE, such as a UE 104 of FIGS. 1 and 3.

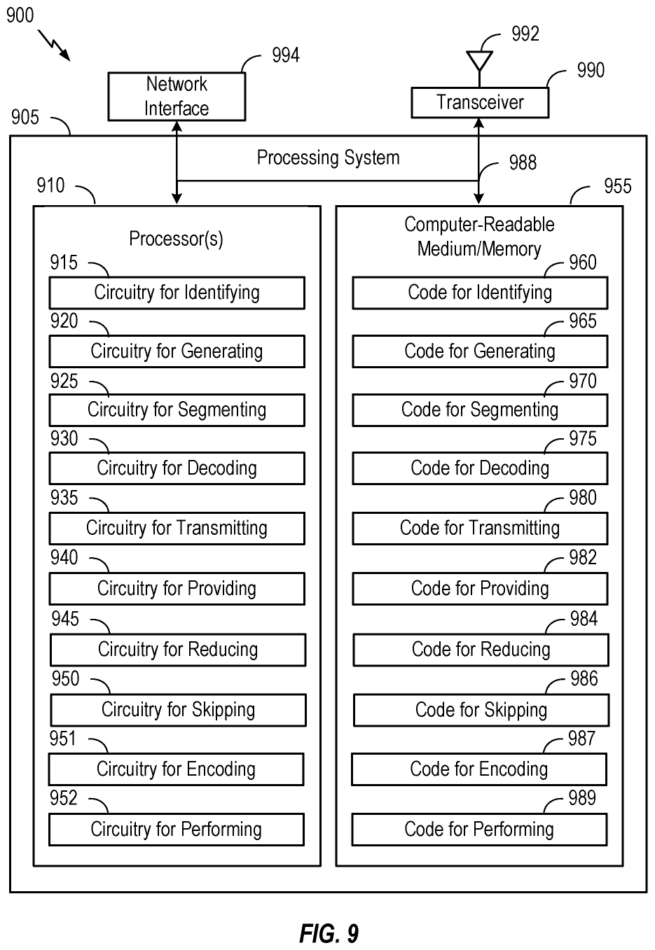

Method 700 begins at step 705 with identifying a set of information bits for transmission. In some cases, the operations of this step refer to, or may be performed by, circuitry for identifying and/or code for identifying as described with reference to FIG. 9.

Method 700 then proceeds to step 710 with generating a set of LLRs corresponding to the set of information bits. In some cases, the operations of this step refer to, or may be performed by, circuitry for generating and/or code for generating as described with reference to FIG. 9.

Method 700 then proceeds to step 715 with segmenting the set of LLRs into a plurality of shaping blocks based, at least in part, on a shaping block length for the plurality of shaping blocks. In some cases, the operations of this step refer to, or may be performed by, circuitry for segmenting and/or code for segmenting as described with reference to FIG. 9.

Method 700 then proceeds to step 720 with decoding, according to a shaping code rate, the plurality of shaping blocks using a polar code to obtain a sequence of shaping bits, wherein the polar code used to decode the plurality of shaping blocks depends on the shaping code rate and the shaping block length. In some cases, the operations of this step refer to, or may be performed by, circuitry for decoding and/or code for decoding as described with reference to FIG. 9.

Method 700 then proceeds to step 725 with generating a sequence of shaped symbols from the sequence of shaping bits. In some cases, the operations of this step refer to, or may be performed by, circuitry for generating and/or code for generating as described with reference to FIG. 9.

Method 700 then proceeds to step 730 with transmitting the sequence of shaped symbols to a receiving device. In some cases, the operations of this step refer to, or may be performed by, circuitry for transmitting and/or code for transmitting as described with reference to FIG. 9.

In some aspects, generating the sequence of shaped symbols comprises: encoding, according to the shaping code rate, the sequence of shaping bits using the polar code to obtain a shaping codeword performing a shaping operation on a subset of the set of information bits to generate a sequence of shaped information bits encoding, using a FEC code rate, the sequence of shaped information bits, the sequence of shaping bits, and a remaining subset of non-shaped information bits of the set of information bits to generate a set of encoded bits in the plurality of shaping blocks generating the sequence of shaped symbols based on the set of encoded bits and the plurality of shaping blocks.

In some aspects, the method 700 further includes transmitting, to the receiving device, configuration information indicating a MCS index value associated with the set of encoded bits, the MCS index value corresponding to an entry in an MCS lookup table that indicates: a modulation order the FEC code rate the shaping code rate. In some cases, the operations of this step refer to, or may be performed by, circuitry for transmitting and/or code for transmitting as described with reference to FIG. 9.

In some aspects, each shaped symbol of the sequence of shaped symbols is associated with a respective symbol probability.

In some aspects, the method 700 further includes providing an indication of each of the respective symbol probabilities to the receiving device. In some cases, the operations of this step refer to, or may be performed by, circuitry for providing and/or code for providing as described with reference to FIG. 9.

In some aspects, providing the indication of each of the respective symbol probabilities comprises transmitting the MCS index value associated with the set of encoded bits to the receiving device, and the entry in the MCS lookup table, corresponding to the MCS index value, further indicates each of the respective symbol probabilities.

In some aspects, providing the indication of each of the respective symbol probabilities comprises transmitting one or more RRC messages including the indication of each of the respective symbol probabilities.

In some aspects, the method 700 further includes, when the shaping block length for the plurality of shaping blocks is greater than a first power of two integer but less than a second power of two integer, reducing the shaping block length for the plurality of shaping blocks to the first power of two integer. In some cases, the operations of this step refer to, or may be performed by, circuitry for reducing and/or code for reducing as described with reference to FIG. 9.

In some aspects, the method 700 further includes, based on the reduced shaping block length for the plurality of shaping blocks, skipping performing the shaping operation on one or more information bits in the subset of the set of information bits. In some cases, the operations of this step refer to, or may be performed by, circuitry for skipping and/or code for skipping as described with reference to FIG. 9.

In some aspects, performing the shaping operation depends on a subband over which the set of information bits will be transmitted.

In some aspects, segmenting the set of LLRs into a plurality of shaping blocks is further based on: a maximum shaping block length for the plurality of shaping blocks a number of resource elements available for transmitting the set of encoded bits a number of shaping blocks of the plurality of shaping blocks.

In some aspects, the maximum shaping block length is fixed in a standards document and is different for uplink transmissions as compared to downlink transmissions.

In some aspects, the method 700 further includes transmitting a RRC message to the receiving device indicating the maximum shaping block length. In some cases, the operations of this step refer to, or may be performed by, circuitry for transmitting and/or code for transmitting as described with reference to FIG. 9.

In some aspects, the shaping code rate depends on a subband over which the set of information bits will be transmitted and is different for different subbands.

In one aspect, method 700, or any aspect related to it, may be performed by an apparatus, such as communications device 900 of FIG. 9, which includes various components operable, configured, or adapted to perform the method 700. Communications device 900 is described below in further detail.

Note that FIG. 7 is just one example of a method, and other methods including fewer, additional, or alternative steps are possible consistent with this disclosure.

### Example Operations of a Receiving Device

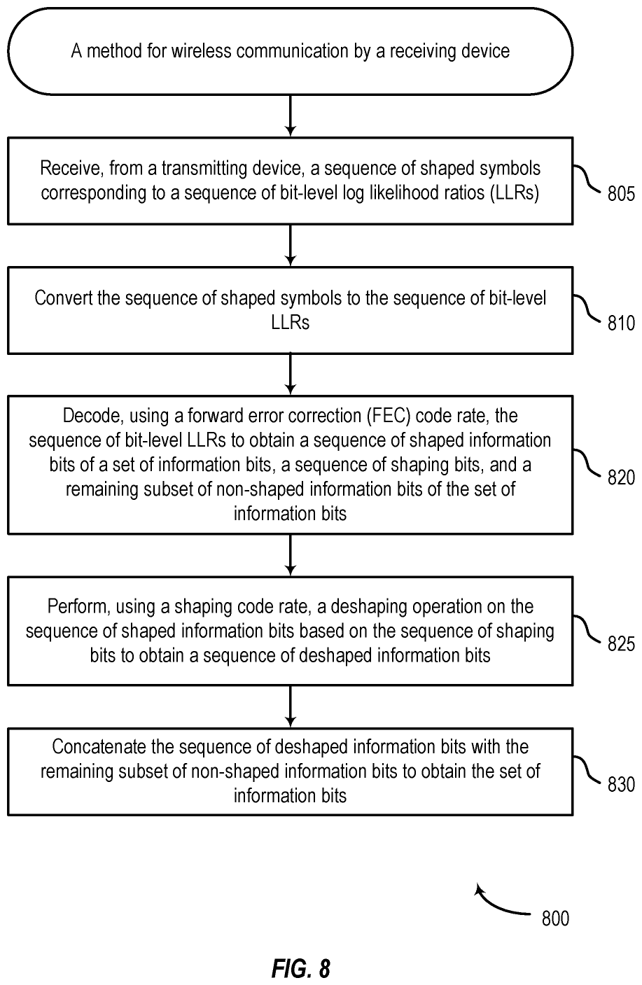

FIG. 8 shows an example of a method 800 for wireless communication by a receiving device. In some aspects, the receiving device is a UE, such as a UE 104 of FIGS. 1 and 3. In some aspects, the receiving device is a network entity, such as a BS 102 of FIGS. 1 and 3, or a disaggregated base station as discussed with respect to FIG. 2.

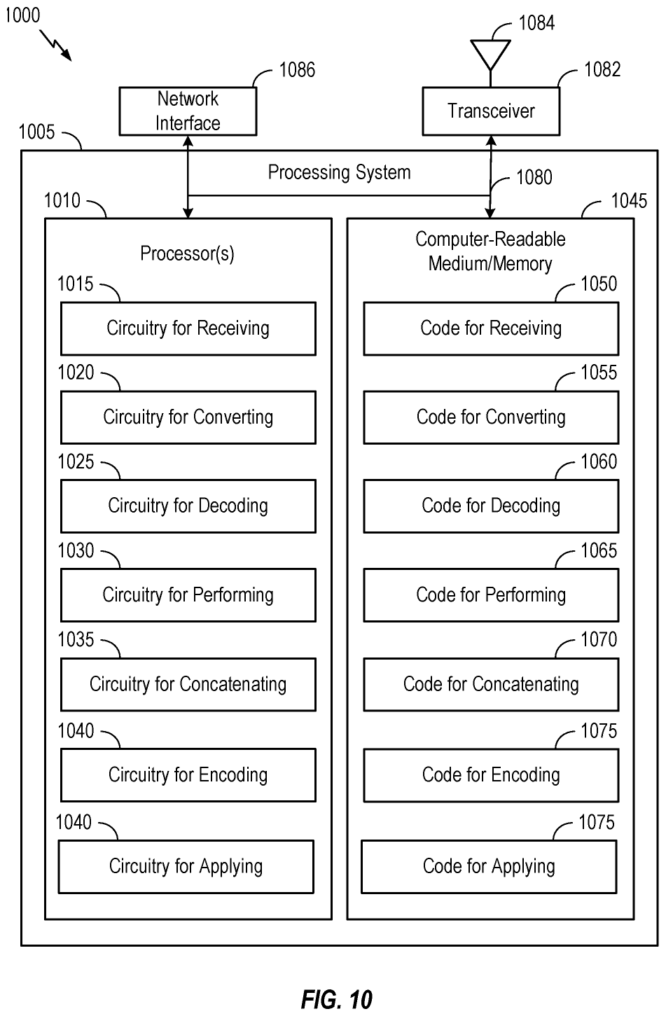

Method 800 begins at step 805 with receiving, from a transmitting device, a sequence of shaped symbols corresponding to a sequence of bit-level log likelihood ratios (LLRs). In some cases, the operations of this step refer to, or may be performed by, circuitry for receiving and/or code for receiving as described with reference to FIG. 10.

Method 800 then proceeds to step 810 with converting the sequence of shaped symbols to the sequence of bit-level LLRs. In some cases, the operations of this step refer to, or may be performed by, circuitry for converting and/or code for converting as described with reference to FIG. 10.

Method 800 then proceeds to step 815 with decoding, using a forward error correction (FEC) code rate, the sequence of bit-level LLRs to obtain a sequence of shaped information bits of a set of information bits, a sequence of shaping bits, and a remaining subset of non-shaped information bits of the set of information bits. In some cases, the operations of this step refer to, or may be performed by, circuitry for decoding and/or code for decoding as described with reference to FIG. 10.

Method 800 then proceeds to step 825 with performing, using a shaping code rate, a deshaping operation on the sequence of shaped information bits based on the sequence of shaping bits to obtain a sequence of deshaped information bits. In some cases, the operations of this step refer to, or may be performed by, circuitry for performing and/or code for performing as described with reference to FIG. 10.

Method 800 then proceeds to step 830 with concatenating the sequence of deshaped information bits with the remaining subset of non-shaped information bits to obtain the set of information bits. In some cases, the operations of this step refer to, or may be performed by, circuitry for concatenating and/or code for concatenating as described with reference to FIG. 10.

In some aspects, performing the deshaping operation on the sequence of shaped information bits comprises encoding the sequence of shaping bits using a polar code and the shaping code rate to generate a deshaping codeword and applying the deshaping codeword to the sequence of shaped information bits to deshape the sequence of shaped information bits and to obtain the sequence of deshaped information bits.

In some aspects, the method 800 further comprising receiving, from the transmitting device, configuration information indicating a modulation and coding scheme (MCS) index value associated with the set of encoded bits, the MCS index value corresponding to an entry in an MCS lookup table that indicates: a modulation order the FEC code rate the shaping code rate. In some cases, the operations of this step refer to, or may be performed by, circuitry for receiving and/or code for receiving as described with reference to FIG. 10.

In some aspects, each shaped symbol of the sequence of shaped symbols is associated with a respective symbol probability. In some aspects, converting the sequence of shaped symbols to the sequence of bit-level LLRs is based on the respective symbol probabilities for each shaped symbol.

In some aspects, the method 800 further includes receiving an indication of each of the respective symbol probabilities from the transmitting device. In some cases, the operations of this step refer to, or may be performed by, circuitry for receiving and/or code for receiving as described with reference to FIG. 10.

In some aspects, receiving the indication of each of the respective symbol probabilities comprises receiving the MCS index value associated with the set of encoded bits from the transmitting device. In some aspects, the entry in the MCS lookup table, corresponding to the MCS index value, further indicates each of the respective symbol probabilities.

In some aspects, receiving the indication of each of the respective symbol probabilities comprises receiving one or more radio resource control (RRC) messages including the indication of each of the respective symbol probabilities.

In some aspects, the shaping code rate depends on a subband over which the set of information bits were transmitted and is different for different subbands.

In one aspect, method 800, or any aspect related to it, may be performed by an apparatus, such as communications device 1000 of FIG. 10, which includes various components operable, configured, or adapted to perform the method 800. Communications device 1000 is described below in further detail.

Note that FIG. 8 is just one example of a method, and other methods including fewer, additional, or alternative steps are possible consistent with this disclosure.

### Example Communications Devices

FIG. 9 depicts aspects of an example communications device 900. In some aspects, communications device 900 is a network entity, such as a BS 102 of FIGS. 1 and 3, or a disaggregated base station as discussed with respect to FIG. 2. In some aspects, communications device 900 is a user equipment, such as a UE 104 described above with respect to FIGS. 1 and 3.

The communications device 900 includes a processing system 905 coupled to the transceiver 990 (e.g., a transmitter and/or a receiver). In some aspects (e.g., when communications device 900 is a network entity), processing system 905 may be coupled to a network interface 994 that is configured to obtain and send signals for the communications device 900 via communication link(s), such as a backhaul link, midhaul link, and/or fronthaul link as described herein, such as with respect to FIG. 2. The transceiver 990 is configured to transmit and receive signals for the communications device 900 via the antenna 992, such as the various signals as described herein. The processing system 905 may be configured to perform processing functions for the communications device 900, including processing signals received and/or to be transmitted by the communications device 900.

The processing system 905 includes one or more processors 910. In various aspects, the one or more processors 910 may be representative of one or more of receive processor 358, transmit processor 364, TX MIMO processor 366, and/or controller/processor 380, as described with respect to FIG. 3. In various aspects, one or more processors 910 may be representative of one or more of receive processor 338, transmit processor 320, TX MIMO processor 330, and/or controller/processor 340, as described with respect to FIG. 3. The one or more processors 910 are coupled to a computer-readable medium/memory 955 via a bus 988. In certain aspects, the computer-readable medium/memory 955 is configured to store instructions (e.g., computer-executable code) that when executed by the one or more processors 910, cause the one or more processors 910 to perform the method 700 described with respect to FIG. 7, or any aspect related to it. Note that reference to a processor performing a function of communications device 900 may include one or more processors 910 performing that function of communications device 900.

In the depicted example, computer-readable medium/memory 955 stores code (e.g., executable instructions), such as code for identifying 960, code for generating 965, code for segmenting 970, code for decoding 975, code for transmitting 980, code for providing 982, code for reducing 984, code for skipping 986, code for encoding 987, and code for performing 989. Processing of the code for identifying 960, code for generating 965, code for segmenting 970, code for decoding 975, code for transmitting 980, code for providing 982, code for reducing 984, code for skipping 986, code for encoding 987, and code for performing 989 may cause the communications device 900 to perform the method 700 described with respect to FIG. 7, or any aspect related to it.

The one or more processors 910 include circuitry configured to implement (e.g., execute) the code stored in the computer-readable medium/memory 955, including circuitry such as circuitry for identifying 915, circuitry for generating 920, circuitry for segmenting 925, circuitry for decoding 930, circuitry for transmitting 935, circuitry for providing 940, circuitry for reducing 945, circuitry for skipping 950, circuitry for encoding 951, and circuitry for performing 952. Processing with circuitry for identifying 915, circuitry for generating 920, circuitry for segmenting 925, circuitry for decoding 930, circuitry for transmitting 935, circuitry for providing 940, circuitry for reducing 945, circuitry for skipping 950, circuitry for encoding 951, and circuitry for performing 952 may cause the communications device 900 to perform the method 700 described with respect to FIG. 7, or any aspect related to it.

Various components of the communications device 900 may provide means for performing the method 700 described with respect to FIG. 7, or any aspect related to it. For example, means for transmitting, sending or outputting for transmission may include transceivers 354 and/or antenna(s) 352 of the ULE 104 illustrated in FIG. 3, transceivers 332 and/or antenna(s) 334 of the BS 102 illustrated in FIG. 3, and/or the transceiver 990 and the antenna 992 of the communications device 900 in FIG. 9. Means for receiving or obtaining may include transceivers 354 and/or antenna(s) 352 of the UE 104 illustrated in FIG. 3, transceivers 332 and/or antenna(s) 334 of the BS 102 illustrated in FIG. 3, and/or the transceiver 990 and the antenna 992 of the communications device 900 in FIG. 9.

FIG. 10 depicts aspects of an example communications device 1000. In some aspects, communications device 1000 is a user equipment, such as a UE 104 described above with respect to FIGS. 1 and 3. In some aspects, communications device 1000 is a network entity, such as a BS 102 of FIGS. 1 and 3, or a disaggregated base station as discussed with respect to FIG. 2.

The communications device 1000 includes a processing system 1005 coupled to the transceiver 1082 (e.g., a transmitter and/or a receiver). In some aspects (e.g., when communications device 1000 is a network entity), processing system 1005 may be coupled to a network interface 1086 that is configured to obtain and send signals for the communications device 1000 via communication link(s), such as a backhaul link, midhaul link, and/or fronthaul link as described herein, such as with respect to FIG. 2. The transceiver 1082 is configured to transmit and receive signals for the communications device 1000 via the antenna 1084, such as the various signals as described herein. The processing system 1005 may be configured to perform processing functions for the communications device 1000, including processing signals received and/or to be transmitted by the communications device 1000.

The processing system 1005 includes one or more processors 1010. In various aspects, the one or more processors 1010 may be representative of one or more of receive processor 358, transmit processor 364, TX MIMO processor 366, and/or controller/processor 380, as described with respect to FIG. 3. In various aspects, one or more processors 1010 may be representative of one or more of receive processor 338, transmit processor 320, TX MIMO processor 330, and/or controller/processor 340, as described with respect to FIG. 3. The one or more processors 1010 are coupled to a computer-readable medium/memory 1045 via a bus 1080. In certain aspects, the computer-readable medium/memory 1045 is configured to store instructions (e.g., computer-executable code) that when executed by the one or more processors 1010, cause the one or more processors 1010 to perform the method 800 described with respect to FIG. 8, or any aspect related to it. Note that reference to a processor performing a function of communications device 1000 may include one or more processors 1010 performing that function of communications device 1000.

In the depicted example, computer-readable medium/memory 1045 stores code (e.g., executable instructions), such as code for receiving 1050, code for converting 1055, code for decoding 1065, code for performing 1070, code for concatenating 1075, code for encoding 1076, and code for applying 1077. Processing of the code for receiving 1050, code for converting 1055, code for decoding 1065, code for performing 1070, code for concatenating 1075, code for encoding 1076, and code for applying 1077 may cause the communications device 1000 to perform the method 800 described with respect to FIG. 8, or any aspect related to it.

The one or more processors 1010 include circuitry configured to implement (e.g., execute) the code stored in the computer-readable medium/memory 1045, including circuitry such as circuitry for receiving 1015, circuitry for converting 1020, circuitry for demapping 1025, circuitry for decoding 1030, circuitry for performing 1035, circuitry for concatenating 1040, circuitry for encoding 1041, and circuitry for applying 1042. Processing with circuitry for receiving 1015, circuitry for converting 1020, circuitry for demapping 1025, circuitry for decoding 1030, circuitry for performing 1035, circuitry for concatenating 1040, circuitry for encoding 1041, and circuitry for applying 1042 may cause the communications device 1000 to perform the method 800 described with respect to FIG. 8, or any aspect related to it.

Various components of the communications device 1000 may provide means for performing the method 800 described with respect to FIG. 8, or any aspect related to it. For example, means for transmitting, sending or outputting for transmission may include transceivers 354 and/or antenna(s) 352 of the UE 104 illustrated in FIG. 3, transceivers 332 and/or antenna(s) 334 of the BS 102 illustrated in FIG. 3, and/or the transceiver 1082 and the antenna 1084 of the communications device 1000 in FIG. 10. Means for receiving or obtaining may include transceivers 354 and/or antenna(s) 352 of the UE 104 illustrated in FIG. 3, transceivers 332 and/or antenna(s) 334 of the BS 102 illustrated in FIG. 3, and/or the transceiver 1082 and the antenna 1084 of the communications device 1000 in FIG. 10.

### Example Clauses

Implementation examples are described in the following numbered clauses:
Clause 1: A method for wireless communication by a transmitting device, comprising: identifying a set of information bits for transmission; generating a set of LLRs corresponding to the set of information bits; segmenting the set of LLRs into a plurality of shaping blocks based, at least in part, on a shaping block length for the plurality of shaping blocks; decoding, according to a shaping code rate, the plurality of shaping blocks using a polar code to obtain a sequence of shaping bits, wherein the polar code used to decode the plurality of shaping blocks depends on the shaping code rate and the shaping block length; generating a sequence of shaped symbols from the sequence of shaping bits; and transmitting the sequence of shaped symbols to a receiving device.
Clause 2: The method of Clause 1, wherein generating the sequence of shaped symbols comprises: encoding, according to the shaping code rate, the sequence of shaping bits using the polar code to obtain a shaping codeword performing a shaping operation on a subset of the set of information bits to generate a sequence of shaped information bits encoding, using a FEC code rate, the sequence of shaped information bits, the sequence of shaping bits, and a remaining subset of non-shaped information bits of the set of information bits to generate a set of encoded bits in the plurality of shaping blocks generating the sequence of shaped symbols based on the set of encoded bits and the plurality of shaping blocks.
Clause 3: The method of Clause 2, further comprising: transmitting, to the receiving device, configuration information indicating a MCS index value associated with the set of encoded bits, the MCS index value corresponding to an entry in an MCS lookup table that indicates: a modulation order the FEC code rate the shaping code rate.
Clause 4: The method of Clause 3, wherein each shaped symbol of the sequence of shaped symbols is associated with a respective symbol probability.
Clause 5: The method of Clause 4, further comprising: providing an indication of each of the respective symbol probabilities to the receiving device.
Clause 6: The method of Clause 5, wherein: providing the indication of each of the respective symbol probabilities comprises transmitting the MCS index value associated with the set of encoded bits to the receiving device, and the entry in the MCS lookup table, corresponding to the MCS index value, further indicates each of the respective symbol probabilities.
Clause 7: The method of Clause 5, wherein providing the indication of each of the respective symbol probabilities comprises transmitting one or more RRC messages including the indication of each of the respective symbol probabilities.
Clause 8: The method of and one of Clauses 2-7, further comprising, when the shaping block length for the plurality of shaping blocks is greater than a first power of two integer but less than a second power of two integer, reducing the shaping block length for the plurality of shaping blocks to the first power of two integer.
Clause 9: The method of Clause 8, further comprising, based on the reduced shaping block length for the plurality of shaping blocks, skipping performing the shaping operation on one or more information bits in the subset of the set of information bits.
Clause 10: The method of any one of Clauses 2-10, wherein segmenting the set of LLRs into the plurality of shaping blocks is further based on: a maximum shaping block length for the plurality of shaping blocks a number of resource elements available for transmitting the set of encoded bits and a number of shaping blocks of the plurality of shaping blocks.
Clause 11: The method of Clause 10, wherein the maximum shaping block length is fixed in a standards document and is different for uplink transmissions as compared to downlink transmissions.
Clause 12: The method of Clause 10, further comprising: transmitting a RRC message to the receiving device indicating the maximum shaping block length.
Clause 13: The method of any one of Clauses 1-12, wherein performing the shaping operation depends on a subband over which the set of information bits will be transmitted.
Clause 14: The method of any one of Clauses 1-13, wherein the shaping code rate depends on a subband over which the set of information bits will be transmitted and is different for different subbands.
Clause 15: A method for wireless communication by a receiving device, comprising: receiving, from a transmitting device, a sequence of shaped symbols corresponding to a sequence of bit-level log likelihood ratios (LLRs); converting the sequence of shaped symbols to the sequence of bit-level LLRs; decoding, using a forward error correction (FEC) code rate, the sequence of bit-level LLRs to obtain a sequence of shaped information bits of a set of information bits, a sequence of shaping bits, and a remaining subset of non-shaped information bits of the set of information bits; performing, using a shaping code rate, a deshaping operation on the sequence of shaped information bits based on the sequence of shaping bits to obtain a sequence of deshaped information bits; and concatenating the sequence of deshaped information bits with the remaining subset of non-shaped information bits to obtain the set of information bits.
Clause 16: The method of Clause 15, wherein performing the deshaping operation on the sequence of shaped information bits comprises: encoding the sequence of shaping bits using a polar code and the shaping code rate to generate a deshaping codeword; and applying the deshaping codeword to the sequence of shaped information bits to deshape the sequence of shaped information bits and to obtain the sequence of deshaped information bits.
Clause 17: The method of Clause 16, further comprising receiving, from the transmitting device, configuration information indicating a modulation and coding scheme (MCS) index value associated with a set of encoded bits, the MCS index value corresponding to an entry in an MCS lookup table that indicates: a modulation order; the FEC code rate; and the shaping code rate.
Clause 18: The method of Clause 17, wherein: each shaped symbol of the sequence of shaped symbols is associated with a respective symbol probability, and converting the sequence of shaped symbols to the sequence of bit-level LLRs is based on the respective symbol probabilities for each shaped symbol.
Clause 19: The method of Clause 18, further comprising receiving an indication of each of the respective symbol probabilities from the transmitting device.
Clause 20: The method of Clause 19, wherein: receiving the indication of each of the respective symbol probabilities comprises receiving the MCS index value associated with the set of encoded bits from the transmitting device, and the entry in the MCS lookup table, corresponding to the MCS index value, further indicates each of the respective symbol probabilities.
Clause 21: The method of Clause 19, wherein receiving the indication of each of the respective symbol probabilities comprises receiving one or more radio resource control (RRC) messages including the indication of each of the respective symbol probabilities.
Clause 22: The method of any one of Clauses 15-21, wherein the shaping code rate depends on a subband over which the set of information bits were transmitted and is different for different subbands.
Clause 23: An apparatus, comprising: a memory comprising executable instructions; and a processor configured to execute the executable instructions and cause the apparatus to perform a method in accordance with any one of Clauses 1-22.
Clause 24: An apparatus, comprising means for performing a method in accordance with any one of Clauses 1-22.
Clause 25: A non-transitory computer-readable medium comprising executable instructions that, when executed by a processor of an apparatus, cause the apparatus to perform a method in accordance with any one of Clauses 1-22.
Clause 26: A computer program product embodied on a computer-readable storage medium comprising code for performing a method in accordance with any one of Clauses 1-22.

### ADDITIONAL CONSIDERATIONS

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method for wireless communication by a transmitting device, comprising:
identifying a set of information bits for transmission;
generating a set of log likelihood ratios (LLRs) corresponding to the set of information bits;
segmenting the set of LLRs into a plurality of shaping blocks based, at least in part, on a shaping block length for the plurality of shaping blocks;
decoding, according to a shaping code rate, the plurality of shaping blocks using a polar code to obtain a sequence of shaping bits, wherein the polar code used to decode the plurality of shaping blocks depends on the shaping code rate and the shaping block length;
generating a sequence of shaped symbols from the sequence of shaping bits; and
transmitting the sequence of shaped symbols to a receiving device.

2. The method of claim 1, wherein generating the sequence of shaped symbols comprises:
encoding, according to the shaping code rate, the sequence of shaping bits using the polar code to obtain a shaping codeword;
performing a shaping operation on a subset of the set of information bits to generate a sequence of shaped information bits;
encoding, using a forward error correction (FEC) code rate, the sequence of shaped information bits, the sequence of shaping bits, and a remaining subset of non-shaped information bits of the set of information bits to generate a set of encoded bits in the plurality of shaping blocks; and
generating the sequence of shaped symbols based on the set of encoded bits and the plurality of shaping blocks.

3. The method of claim 2, further comprising transmitting, to the receiving device, configuration information indicating a modulation and coding scheme (MCS) index value associated with the set of encoded bits, the MCS index value corresponding to an entry in an MCS lookup table that indicates:
a modulation order;
the FEC code rate; and
the shaping code rate.

4. The method of claim 3, wherein each shaped symbol of the sequence of shaped symbols is associated with a respective symbol probability.

5. The method of claim 4, further comprising providing an indication of each of the respective symbol probabilities to the receiving device.

6. The method of claim 5, wherein:
providing the indication of each of the respective symbol probabilities comprises transmitting the MCS index value associated with the set of encoded bits to the receiving device; and
the entry in the MCS lookup table, corresponding to the MCS index value, further indicates each of the respective symbol probabilities.

7. The method of claim 5, wherein providing the indication of each of the respective symbol probabilities comprises transmitting one or more radio resource control (RRC) messages including the indication of each of the respective symbol probabilities.

8. The method of claim 2, further comprising, when the shaping block length for the plurality of shaping blocks is greater than a first power of two integer but less than a second power of two integer, reducing the shaping block length for the plurality of shaping blocks to the first power of two integer.

9. The method of claim 8, further comprising, based on the reduced shaping block length for the plurality of shaping blocks, skipping performing the shaping operation on one or more information bits in the subset of the set of information bits.

10. The method of claim 1, wherein segmenting the set of LLRs into the plurality of shaping blocks is further based on:
a maximum shaping block length for the plurality of shaping blocks;
a number of resource elements available for transmitting the set of encoded bits; and
a number of shaping blocks of the plurality of shaping blocks.

11. The method of claim 10, wherein the maximum shaping block length is fixed in a standards document and is different for uplink transmissions as compared to downlink transmissions.

12. The method of claim 10, further comprising transmitting a radio resource control (RRC) message to the receiving device indicating the maximum shaping block length.

13. The method of claim 1, wherein performing the shaping operation depends on a subband over which the set of information bits will be transmitted.

14. The method of claim 1, wherein the shaping code rate depends on a subband over which the set of information bits will be transmitted and is different for different subbands.

15. A method for wireless communication by a receiving device, comprising:
receiving, from a transmitting device, a sequence of shaped symbols corresponding to a sequence of bit-level log likelihood ratios (LLRs);
converting the sequence of shaped symbols to the sequence of bit-level LLRs;
decoding, using a forward error correction (FEC) code rate, the sequence of bit-level LLRs to obtain a sequence of shaped information bits of a set of information bits, a sequence of shaping bits, and a remaining subset of non-shaped information bits of the set of information bits;
performing, using a shaping code rate, a deshaping operation on the sequence of shaped information bits based on the sequence of shaping bits to obtain a sequence of deshaped information bits; and
concatenating the sequence of deshaped information bits with the remaining subset of non-shaped information bits to obtain the set of information bits.

16. The method of claim 15, wherein performing the deshaping operation on the sequence of shaped information bits comprises:
encoding the sequence of shaping bits using a polar code and the shaping code rate to generate a deshaping codeword; and
applying the deshaping codeword to the sequence of shaped information bits to deshape the sequence of shaped information bits and to obtain the sequence of deshaped information bits.

17. The method of claim 16, further comprising receiving, from the transmitting device, configuration information indicating a modulation and coding scheme (MCS) index value associated with a set of encoded bits, the MCS index value corresponding to an entry in an MCS lookup table that indicates:
a modulation order;
the FEC code rate; and
the shaping code rate.

18. The method of claim 17, wherein:
each shaped symbol of the sequence of shaped symbols is associated with a respective symbol probability; and
converting the sequence of shaped symbols to the sequence of bit-level LLRs is based on the respective symbol probabilities for each shaped symbol.

19. The method of claim 18, further comprising receiving an indication of each of the respective symbol probabilities from the transmitting device.

20. The method of claim 19, wherein:
receiving the indication of each of the respective symbol probabilities comprises receiving the MCS index value associated with the set of encoded bits from the transmitting device; and
the entry in the MCS lookup table, corresponding to the MCS index value, further indicates each of the respective symbol probabilities.

21. The method of claim 19, wherein receiving the indication of each of the respective symbol probabilities comprises receiving one or more radio resource control (RRC) messages including the indication of each of the respective symbol probabilities.

22. The method of claim 1, wherein the shaping code rate depends on a subband over which the set of information bits were transmitted and is different for different subbands.

23. An apparatus for wireless communication, comprising:
a memory comprising executable instructions; and
a processor configured to execute the executable instructions and cause the apparatus to:
identify a set of information bits for transmission;
generate a set of log likelihood ratios (LLRs) corresponding to the set of information bits;
segment the set of LLRs into a plurality of shaping blocks based, at least in part, on a shaping block length for the plurality of shaping blocks;
decode, according to a shaping code rate, the plurality of shaping blocks using a polar code to obtain a sequence of shaping bits, wherein the polar code used to decode the plurality of shaping blocks depends on the shaping code rate and the shaping block length;
generate a sequence of shaped symbols from the sequence of shaping bits; and
transmit the sequence of shaped symbols to a receiving device.

24. The apparatus of claim 23, wherein, in order to generate the sequence of shaped symbols, the processor is further configured to cause the apparatus to:
encode, according to the shaping code rate, the sequence of shaping bits using the polar code to obtain a shaping codeword;
perform a shaping operation on a subset of the set of information bits to generate a sequence of shaped information bits;
encode, using a forward error correction (FEC) code rate, the sequence of shaped information bits, the sequence of shaping bits, and a remaining subset of non-shaped information bits of the set of information bits to generate a set of encoded bits in the plurality of shaping blocks; and
generate the sequence of shaped symbols based on the set of encoded bits and the plurality of shaping blocks.

25. The apparatus of claim 24, wherein the processor is further configured to cause the apparatus to transmit, to the receiving device, configuration information indicating a modulation and coding scheme (MCS) index value associated with the set of encoded bits, the MCS index value corresponding to an entry in an MCS lookup table that indicates:
a modulation order;
the FEC code rate; and
the shaping code rate.

26. The apparatus of claim 25, wherein:
each shaped symbol of the sequence of shaped symbols is associated with a respective symbol probability;
the processor is further configured to cause the apparatus to provide an indication of each of the respective symbol probabilities to the receiving device;
in order to provide the indication of each of the respective symbol probabilities, the processor is further configured to cause the apparatus to transmit the MCS index value associated with the set of encoded bits to the receiving device; and
the entry in the MCS lookup table, corresponding to the MCS index value, further indicates each of the respective symbol probabilities.

27. An apparatus for wireless communication, comprising:
a memory comprising executable instructions; and
a processor configured to execute the executable instructions and cause the apparatus to:
receive, from a transmitting device, a sequence of shaped symbols corresponding to a sequence of bit-level log likelihood ratios (LLRs);
convert the sequence of shaped symbols to the sequence of bit-level LLRs;
decode, using a forward error correction (FEC) code rate, the sequence of bit-level LLRs to obtain a sequence of shaped information bits of a set of information bits, a sequence of shaping bits, and a remaining subset of non-shaped information bits of the set of information bits;
perform, using a shaping code rate, a deshaping operation on the sequence of shaped information bits based on the sequence of shaping bits to obtain a sequence of deshaped information bits; and
concatenate the sequence of deshaped information bits with the remaining subset of non-shaped information bits to obtain the set of information bits.

28. The apparatus of claim 27, wherein, in order to perform the deshaping operation on the sequence of shaped information bits, the processor is further configured to cause the apparatus to:
encode the sequence of shaping bits using a polar code and the shaping code rate to generate a deshaping codeword; and
apply the deshaping codeword to the sequence of shaped information bits to deshape the sequence of shaped information bits and to obtain the sequence of deshaped information bits.

29. The apparatus of claim 28, wherein the processor is further configured to cause the apparatus to receive, from the transmitting device, configuration information indicating a modulation and coding scheme (MCS) index value associated with a set of encoded bits, the MCS index value corresponding to an entry in an MCS lookup table that indicates:
a modulation order;
the FEC code rate; and
the shaping code rate.

30. The apparatus of claim 29, wherein:
each shaped symbol of the sequence of shaped symbols is associated with a respective symbol probability;
the processor is configured to cause the apparatus to convert the sequence of shaped symbols to the sequence of bit-level LLRs based on the respective symbol probabilities for each shaped symbol;
the processor is further configured to cause the apparatus to receive an indication of each of the respective symbol probabilities from the transmitting device;
in order to receive the indication of each of the respective symbol probabilities, the processor is further configured to cause the apparatus to receive the MCS index value associated with the set of encoded bits from the transmitting device; and
the entry in the MCS lookup table, corresponding to the MCS index value, further indicates each of the respective symbol probabilities.
